(19) United States
(12) Patent Application Publication
(10) Pub. No.: US 2004/0067324 A1
(43) Pub. Date: Apr. 8, 2004

(54) Organic photosensitive optoelectronic device

(76) Inventors: Pavel I. Lazarev, Belmont, CA (US); Victor V. Nazarov, Moscow Region (RU)

Correspondence Address: DORSEY & WHITNEY LLP, INTELLECTUAL PROPERTY DEPARTMENT, 4 EMBARCADERO CENTER, SUITE 3400, SAN FRANCISCO, CA, 94111, US

(21) Appl. No.: 10/656,578

(22) Filed: Sep. 4, 2003

Related U.S. Application Data
(60) Provisional application No. 60/410,514, filed on Sep. 13, 2002.

(51) Int. Cl. C09K 19/00

(52) U.S. Cl. 428/1.31

(57) ABSTRACT

An organic optoelectronic device is provided which comprises a multi-layer structure and a substrate. The multi-layer structure is comprised of a first electrode layer, a second electrode layer, and at least one organic photoelectric layer. The organic photoelectric layer is an anisotropically absorbing and electrically conducting layer and comprised of rodlike supramolecules which comprise at least one polycyclic organic compound with a conjugated π-system, has a globally ordered crystal structure with an intermolecular spacing of 3.4±0.3 A along a polarization axis of the organic photoelectric layer, and absorbs electromagnetic radiation in a predetermined spectral subrange of approximately 200 to 3000 nm. The multi-layer structure is formed on one side of the substrate. At least one of the first and second electrodes is transparent for the electromagnetic radiation to which the optoelectronic device is sensitive.

### CROSS REFERENCE TO RELATED APPLICATIONS

This application claims the priority of the U.S. Provisional Patent Application serial No. 60/410,514, filed Sep. 13, 2002, the disclosure of which is hereby incorporated by reference in its entirety.

### FIELD OF THE INVENTION

The present invention generally relates to organic thin-film photosensitive optoelectronic devices. More specifically, the present invention is directed to organic photosensitive optoelectronic devices intended for converting radiation into electricity and particularly for converting solar energy into electrical energy (solar cells), and to organic photosensitive optoelectronic devices intended for signal detection (photoconductors cell and photodetectors). More specifically, the present invention features the use of organic photovoltaic materials.

### BACKGROUND OF THE INVENTION

Photovoltaic (photoelectric) devices convert electromagnetic radiation into electricity. Such devices are used to drive power consuming loads so as to provide, for example, lighting or heating, or to operate electronic equipment. Thereby, an electronic device connected to a photovoltaic source as the external resistive load (e.g., a computer monitor, display, exposure meter, etc.) can operate using converted solar energy. These power generation applications often involve the charging of batteries or other energy storage devices, so that equipment operation may continue when direct illumination from the sun or other ambient light source is no longer available. As used herein, the term “resistive load” refers to any power consuming or storing device, equipment or system.

Another type of photosensitive optoelectronic device is a photoconductor cell. In this function, signal detection circuitry monitors the resistance of the device to detect changes due to the absorption of light. Another type of photosensitive optoelectronic device is a photodetector. In operation a photodetector has a voltage applied and a current detecting circuit measures the current generated when the photodetector is exposed to electromagnetic radiation. A detecting circuit as described herein is capable of providing a bias voltage to a photodetector and measuring the electronic response of the photodetector to ambient electromagnetic radiation. These three classes of photosensitive optoelectronic devices may be characterized according to whether a rectifying junction as defined below is present and also according to whether the device is operated with an external applied voltage, also known as a bias or bias voltage. A photoconductor cell does not have a rectifying junction and is normally operated with a bias. A photovoltaic device has at least one rectifying junction and is operated with no bias. A photodetector has at least one rectifying junction and is usually but not always operated with a bias.

Photovoltaic devices produce a photogenerated built-in voltage when they are connected across a resistive load and are irradiated by light. When irradiated without any external resistive load, a photovoltaic device generates its maximum possible built-in voltage V called open-circuit voltage (Voc). If a photovoltaic device is irradiated with its electrical contacts shorted, a maximum short-circuit current (Isc), is produced. When actually used to generate power, a photovoltaic device is connected to a finite resistive load and the power output is given by the product of the current and voltage, I×V. The maximum total power generated by a photovoltaic device is inherently uncapable of exceeding the product Isc×Voc. When the load value is optimized for maximum power extraction, the current and voltage have values Imax and Vmax, respectively.

The estimation of conversion efficiency of a photovoltaic device is the fill factor, ff, defined as

ff=(Imax·Vmax)/(Isc·Voc),

where ff is always less than unity, as Isc and Voc are never obtained simultaneously in actual use. Nevertheless, as ff approaches 1, the device is more efficient.

Other criteria of the efficiency of a photovoltaic device can be used as well. In particular, the external quantum efficiency characterizes the number of electrons generated per one incident radiation quantum (photon) and the internal quantum efficiency is the number of electrons produced per one photon absorbed by the photovoltaic device.

It is similarly possible to give definition of efficiency for other photosensitive optoelectronic devices.

There are photosensitive optoelectronic devices of various types (solar cells, photodetectors, photoresistors, etc.) based on inorganic semiconductors (see, e.g., S. M. Sze, Physics of Semiconductor Devices, Wiley-Interscience, New York, 1981). Inorganic semiconductors (such as crystalline, polycrystalline, and amorphous silicon, gallium arsenide, and cadmium telluride) were the main materials used for the development of solar cells. The term “semiconductor” refers to a material capable of conducting electric current, in which the free carriers of the electric charge (electrons and holes) are generated by means of thermal or electromagnetic excitation.

Conventional photovoltaic devices or photovoltaic elements typically comprise a p-n junction formed in a single crystal semiconductor (e.g., silicon) substrate. Typically, an n-type surface region is diffused into ap-type silicon substrate and ohmic contacts are applied. When the device is exposed to solar radiation, photons incident upon the n-type surface travel to the junction and the p-type region where they are absorbed in the production of electron-hole pairs.

The conversion efficiency of these conventional photovoltaic devices, however, is limited by a number of factors. First, the built-in voltage is limited by a relatively narrow bandgap of silicon and by the limited extent to which both p- and n-type layers of silicon can be doped. While the built-in voltage of the device can be increased through increased doping of both layers forming the junction, such excess doping tends to reduce conversion efficiency by reducing the lifetime of the carriers and thereby the collection efficiency of the device. As a consequence, the open-circuit voltage of a typical silicon photovoltaic device is only about 50% of the silicon bandgap value. Second, silicon tends to absorb high-energy photons, that is, blue and ultraviolet light, very close to the surface (typically within a micron thick layer). As a consequence, many of the high-energy photons are absorbed near the surface of the n-type region, causing charge carriers generated by such absorption to recombine at the surface and be lost as mediators of photocurrent. Still a third limiting factor resides in the fact that photons of lower energy, representing red light and near infrared radiation, tend to penetrate deeply into the silicon before they are absorbed. While minority carriers created by deep-layer absorption can contribute to the photocurrent if minority carrier lifetimes are sufficient to permit them to drift into the junction region, the high-temperature diffusion step required to form the n-type region significantly reduces the minority carrier lifetime in p-type silicon substrates. As a consequence, many charge carriers created by deep absorption are also lost as mediators of photocurrent.

As noted above, photovoltaic devices (including solar cells) are characterized by the efficiency of converting solar energy into useful electricity. Silicon-based photovoltaic devices allowed reaching relatively high conversion efficiencies, on a level of 12-15%. The conversion efficiency of a particular photovoltaic device significantly depends on the quality of materials employed. For example, important limiting factor in real devices are leak currents caused by recombination of photoproduced charge carriers. In other words, undesired electron-hole interactions causes a part of electrons to return to the valence band of the semiconductor or to localize on allowed energy levels in the forbidden band of the semiconductor. The leak currents are usually caused by the presence of dotted (point) defects or other deviations from the ideal crystalline structure of a semiconductor, which lead to the appearance of such allowed energy states in the forbidden band.

Only when the amount and influence of the aforementioned defects are small, the electron-hole interactions proceed by mechanism of the so-called radiative recombination. Possessing a sufficiently large characteristic time, the radiative recombination belongs to “slow” processes. Thus, in the absence of defects, the process of radiative recombination offers the only channel for decay of the electron-hole pairs. This process involving no local energy levels, the radiative recombination can proceed directly from conduction to valence band. As a result, a high efficiency of converting solar energy into electricity is an indirect evidence of the absence of more rapid (i.e., more effective) channels of nonradiative recombination in a given material.

There are some other disadvantages of photovoltaic devices based on inorganic semiconductors, besides those mentioned above. In particular, such devices are very expensive. Manufacturing these devices requires complicated technologies involving high-cost equipment and processing methods, which are only capable of providing semiconductor layers and multilayer structures of large area and free of defects.

There were numerous attempts at reducing the cost of production of photosensitive optoelectronic devices including solar cells. Organic photoconductors and organic semiconductors were considered as candidate materials because of the option to produce organic films by deposition from solutions or by analogous low-cost techniques. However, the conversion efficiency of solar cells employing this organic material was very low (not exceeding 0.05%) even under the conditions of irradiation at an incident light intensity of 100 mW/cm². Practical on-ground applications require greater values of the photovoltaic conversion efficiency.

Now we will briefly consider the physical principles underlying operation of photovoltaic devices based on organic semiconductors and define the main terms used in what follows.

When electromagnetic radiation of an appropriate energy is incident upon a semiconducting organic material, for example, an organic molecular crystal, a photon can be absorbed to produce an excited molecular state. This is represented symbolically as S₀+hν [symbol] S₀*, where S₀ and S₀* denote ground and excited molecular states, respectively. This energy absorption is associated with the promotion of an electron from a bound state in the highest occupied molecular orbital (HOMO), which may be a π bond, to the lowest unoccupied molecular orbital (LUMO), which may be a π* bond, or equivalently, the promotion of a hole from the LUMO to the HOMO. In organic thin-film photoconductors, the generated molecular state is generally believed to be an exciton. Exciton is an elementary electrically neutral excitation possessing a quasiparticle character in semiconductors. In organic semiconductors, excitons appears upon the formation of electron-hole pairs following the HOMO-LUMO transition. If the photoexcitation energy is smaller than the HOMO-LUMO energy difference, the electron and hole cannot independently move in the semiconductor material and occur in the bound state, representing an electrically neutral quasiparticle (exciton). Traveling in the semiconductor material, excitons carry the energy. The excitons can have an appreciable lifetime before geminate recombination, which refers to the process of the original electron and hole recombination with each other, as opposed to recombination with holes or electrons from other pairs. Thus, the process of photon absorption in organic semiconductors leads to the creation of bound electron-hole pairs (excitons). The excitons can diffuse toward the so-called dissociation centers, where the positive and negative charges can separate. Such dissociation can be realized, for example, at a boundary (interface) of two organic materials, provided that one of these materials has a greater electron affinity (EA) and the other possesses a lower ionization potential (IP). The material of higher EA can accept electrons from the conduction band of the other material and is called electron acceptor. The material possessing a lower ionization potential can accept holes from the valence band of the organic semiconductor in contact, the former material is called the hole acceptor or the electron donor, because it can also donate electrons to an adjacent acceptor. It should be noted that a difference between IP and EA must be sufficiently large so as to overcome the energy of exciton binding (the latter is typically around 0.4 eV). Otherwise excitons do not dissociate (the bound electron-hole pairs do not separate into free charge carriers) and such bound charges eventually recombine at the interface between donor and acceptor materials. Being separated, the charges move toward the corresponding electrodes of the photovoltaic device: holes drifting to the anode and electrons-to the cathode, thus creating the electric current. Therefore, in contrast to inorganic semiconductors, where mobile charge carriers are formed directly upon the absorption of light, the mobile charge carriers in the molecular (organic) semiconductors such as porphyrins, perylenes, and phthalocyanines appear as a result of the decomposition of excitons formed upon light absorption.

The electron-hole pair representing an exciton can be separated in the region of an internal electric field generated in the semiconductor material. To produce such internally generated electric fields occupying a substantial volume, the usual method is to juxtapose two layers of material with appropriately selected conduction properties, especially with respect to their distribution of molecular quantum energy states. The interface of these two materials is called a photovoltaic heterojunction. In traditional semiconductor theory, materials for forming photovoltaic heterojunctions have been denoted as generally being of either n (donor) orp (acceptor) type. Here, n-type denotes that the majority carrier type is electron. This could be viewed as the type of materials having many electrons in relatively free energy states. The p-type indicates that the majority carrier type is a hole. Such materials have many holes in relatively free energy states. The type of the background (that is, not photogenerated) majority carrier and their concentration depend primarily on the unintentional doping by defects or impurities. The type and concentration of impurities determine the value of the Fermi energy, or the Fermi level position, within the gap between the lowest unoccupied molecular orbital (LUMO) and the highest occupied molecular orbital (HOMO), called the LUMO-HOMO gap. The Fermi energy characterizes the statistical occupation of molecular quantum energy states, representing the value of energy for which the probability of occupation is equal to 0.5. The Fermi level position near the LUMO energy indicates that electrons are the predominant carrier type. The Fermi energy being close to the HOMO energy indicates that holes are the predominant carriers.

There are the so-called self-assembling solar cells based on a mixture of a crystalline dye and a liquid crystal material. The mixture is capable of self-organizing with the formation of a thin photoelectric film characterized by high photovoltaic conversion efficiency. The liquid crystal component represents an organic compound belonging to hexabenzocoronenes whose disc-shaped molecules are capable of forming liquid crystal phase at room temperature. These molecules are aggregated into columns (stacks) effectively conducting at room temperature. The dye component represents a perylene dye. A solution of two components in chloroform is applied onto a solid substrate by centrifuging. Then the solvent is evaporated to leave the substrate covered by a self-organizing layer in which the perylene dye is crystallized. The interface between two organic materials features the light-induce charge separation. The quantum efficiency of photovoltaic devices implementing such organic heterojunctions reaches 34%, which implies that each 100 absorbed photons yield on the average 34 electron-hole pairs.

Also described in literature were photovoltaic devices based on the organic compounds of some other types such as ruthenium-containing bipyridines. An examples is offered by cis-X2-bis(2,2′-bipyrididyl-4,4′-dicarboxylate)ruthenium(II), r [symbol] e X═Cl—, Br—, I—, CN—, SCN— (see. M. K. Nazeeruddin et al., J. Am. Chem. Soc., Vol. 115, No. 14, 6382-6390 (1993)).

There is a known photovoltaic converter based on a MEH-PPV copolymer and a perylene derivative (PPEI) (see J. J. Dittmer et al., Synthetic Metals, Vol. 102, 879-880 (1999)). In this system, MEH-PPV acts as a hole acceptor and PPEI, as the electron acceptor (hole donor). Excitons photogenerated in the organic semiconductor subsequently decay into free charge carriers (electrons and holes) at the interface between the donor and acceptor components. The introduction of PPEI significantly increases the external quantum efficiency of photovoltaic devices employing this system. The PPEI particles are distributed in the MEH-PPV matrix volume over a distance equal to the exciton diffusion length (˜9 nm). In presence of PPEI stimulates charge separation in thin-film MEH-PPV structures.

There are known examples of using other perylene pigments of the n-type, such as tetracarboxyldiimide, as well as perylene pigments with N-methyl groups replaced by N-(ditert-butylphenyl) groups, which increases the photocurrent generated in photovoltaic devices. (see M. Hiramoto et al., Appl. Phys. Lett., Vol. 64, No. 2, 187-189 (1994)).

A general disadvantage of the organic materials used in the aforementioned photovoltaic devices consists in the fact that the organic layers possess no globally ordered crystal structure. For this reason, the mobility of electrons and holes in these layers is much lower as compared to that in the same bulk crystalline materials. As a result, electrons and holes do not leave the active region of a semiconductor structure during the exciton lifetime and recombine. Such electron-hole pairs do not contribute to the photocurrent and the photovoltaic conversion efficiency decreases. In addition, a decrease in the electron and hole mobility leads to an increase in the resistivity of the material and, hence, in the serial resistance of the photovoltaic device. This implies increase of ohmic losses and additional decrease in the photovoltaic conversion efficiency. Another disadvantage of the aforementioned photovoltaic devices employing organic films without globally ordered crystal structure is that these materials are characterized by extremely small diffusion length of photogenerated excitons. This necessitates using photovoltaic structures consisting of very thin layers of thicknesses comparable with the exciton diffusion length, which also decreases both external and internal quantum efficiency of such devices.

There is a known photovoltaic cell (Klaus Petritsch, PhD Thesis, “Organic Solar Cell Architectures”, Cambridge and Graz, July 2000, Chapter 3, Single Layer Devices, p. 31) based on a Schottky barrier containing the active layer of an organic semiconductor forming a rectifying junction with electrode. This organic layer is based on undoped poly(acetylene) and has a thickness approximately equal to the depth of a depleted layer. The electrode contains a thin layer of magnesium known to form a rectifying Schottky barrier in contact with poly(acetylene). The magnesium layer is overcoated with a gold film.

Another known photovoltaic cell (Klaus Petritsch, PhD Thesis, “Organic Solar Cell Architectures”, Cambridge and Graz, July 2000, Chapter 4, Double Layer Devices, p. 67) comprises the first layer of an organic electron donor material in contact with the second layer made of an organic electron acceptor material. At least one of these materials is capable of absorbing light in a wavelength range from 350 to 1000 nm and the two materials in contact for a rectifying junction. The cell is provided with electrodes forming ohmic contacts at least with a part of the surface of organic layers. A distinctive feature of said photovoltaic cell is that the organic materials employed contain organic compounds with generally planar polycyclic nuclei. These compounds are capable of forming a layer structure with a total thickness not exceeding 0.5 micron.

The variant of double layer photovoltaic cell, which comprises the first layer of an organic electron donor material in contact with the second layer of an organic electron acceptor material, is possible. The two foregoing layers are capable of absorbing light in the predetermined wavelength range, for example from 350 to 1000 nm. The cell is provided with electrodes forming ohmic contacts with the organic layers. At least one of these electrodes is transparent for electromagnetic radiation to which the photoelectric junction is sensitive.

One more variant of double layer photovoltaic cell is based on a heterojunction comprising two layers made of different semiconducting materials. The first layer, absorbing the incident light, is made of a polymeric material possessing a resistivity below 10⁶ Ω·cm. The second layer is made of an inorganic semiconductor. The two semiconductors possess different forbidden bandwidths, the bandgaps value of the first layer being greater than that of the second layer, and their contact represents a heterojunction. The first layer exhibits electric conductivity of one type (e.g., n-type), while the second layer may be either of the same (n) or different (p) type). The disclosed photovoltaic cell is provided with electrodes (formed on both semiconductor layers) for connecting to an external circuit. The electrodes on the first layer are transparent for the incident electromagnetic radiation.

The usage of photoreflective electrode is possible, which ensures an increase in the photovoltaic conversion efficiency of solar cell by doubly transmitting radiation through the active layers. This cell comprises a substrate coated with a photoreflective electrode layer, a photoelectric layer, and the upper transparent electrode.

A way to increase the photovoltaic conversion efficiency consists in using multicell arrays.

Various methods have been developed for manufacturing thin layers capable of forming the structure of organic photosensitive optoelectronic devices.

There is a known method for the epitaxial growth of thin layers composed of large anisotropic organic molecules on inorganic substrates. According to this, the deposition process or mass transfer is produced via a VPE process in a vacuum chamber. This VPE technique was successfully used for obtaining layers of organic molecules on graphite, alkali halide, and some other suitable materials [see N. Uyeda, T. Kobayashi, E. Suito, Y. Harada, and M. Watanabe, J. Appl. Phys. 43(12), 5181 (1972); M. Ashida, Bull. Chem. Soc. Jpn. 39(12), 2625-2631, 2632-2638 (1966); H. Saijo, T. Kobayashi, and N. Uyeda, J. Crystal Growth 40, 118-124 (1977); M. Ashida, N. Uyeda and E. Suito, J. of Crystal Growth 8, 45-56 (1971); Y. Murata, J. R. Fryer and T. Baird, J. Microsc., 108(3), 261-275 (1976); J. R. Fryer, Acta Cryst. A35, 327-332 (1979); M. Ashida, N. Uyeda, and E. Suito, Bull. Chem. Soc. Jpn. 39(12), 2616-2624 (1966); Y. Saito and M. Shiojiri, J. Crystal Growth 67, 91 (1984); and Y. Saito, Appl. Surf. Sci. 22/23, 574-581 (1985)).

Also known are the methods for epitaxial growth and polymerization of synthetic polymers and biopolymers on alkali halide substrates from solutions, melts, and vapor phase. There are examples of using other inorganic minerals as substrates [(see. A. Mcpherson and P. J. Schlichto, J. Cryst. Growth 85, 206 (1988)].

There are several disadvantages inherent in inorganic single crystals, which limit the possibilities of using such crystals as substrates for epitaxial growth. In particular, the number of single crystal materials suited for epitaxial growth is rather restricted because the crystal surface can be reactive, and/or covered with oxides, and/or contain adsorbed water molecules. The substrate can be nontransparent, possess undesired electronic and/or thermal properties, and so on.

There is a known method for the formation of bilayer films involving a substrate at least one surface of which is at least partially covered with the first layer (called “seed” layer, which will be referred to below as the alignment layer) of a crystalline, uniaxial oriented organic compound, and contains the second layer of a crystalline uniaxial oriented organic compound formed above the first layer, whereby the second layer is subjected during its growth to the aligning action of the first layer. The second layer will be referred to below as the epitaxial layer.

The disadvantage of said known VPE technology is limitation on the substrate materials: only substances retaining their physical, mechanical, optical, and their properties under the conditions of large pressure differences, high vacuum, and considerable temperature gradients can be employed. Besides, the requirement of matching between crystal lattices of the substrate and the growing film restricts the list of compounds suitable for deposition.

One of the major general disadvantages of VPE is a strong influence of defects, present on the initial substrate surface, upon the structure of a deposited layer. The deposition of molecules from the vapor phase enhances and/or decorates defects on the substrate surface.

It is possible such method of film deposition, at which the overgrowth of a film is carried out from a solution. This method is limited to soluble compounds; however, most of solvents are highly hazardous liquids, which make manufacturing difficult and expensive. Also, the deposition process is hindered in cases of low wetting ability of the substrate surface.

Another method for thin crystal film (layer) manufacturing is described as Optiva process [see: U.S. Pat. Nos. 5,739,296 and 6,049,428 and in the following publications: P. Lazarev, et al., “X-ray Diffraction by Large Area Organic Crystalline Nanofilms”, Molecular Materials, 14(4), 303-311 (2001), and Bobrov, Y. “Spectral properties of Thin Crystal Film Polarizers” Molecular Materials, 14(3), 191-203 (2001)]. This process involves a chemical modification step and four steps of ordering during the crystal film formation. Said multistage process in the further statement will be referred to as Cascade Crystallization Process. The chemical modification step introduces hydrophilic groups on the periphery of the molecule in order to impart amphiphilic properties to the molecule. Amphiphilic molecules stack together in supramolecules, which is first step of ordering. By choosing specific concentration, supramolecules are converted into a liquid-crystalline state to form a lyotropic liquid crystal, which is the second step of ordering. The lyotropic liquid crystal is deposited under the action of a shear force (or meniscus force) onto a substrate, so that the shear force (or the meniscus) direction determines the crystal axis direction in the resulting solid crystal film. This shear-force-assisted directional deposition is the third step of ordering, representing global ordering of the crystalline or polycrystalline structure on the substrate surface. The last, fourth step of the Cascade Crystallization Process is drying/crystallization, which converts the lyotropic liquid crystal into a solid crystal film. In this disclosure we will use the term Cascade Crystallization Process to refer to the chemical modification and four ordering steps as a combined process.

The layers produced by this method possess a global order. This means that the direction of the crystallographic axis of the layer over the entire substrate surface is controlled by the deposition process, with a limited influence of the substrate surface. The major advantage of the Cascade Crystallization Process is a weak dependence of the layer on the surface defects of substrate. This weak dependence is due to the viscous and elastic properties of the lyotropic liquid crystal. The elastic layer of a liquid crystal prevents the development of the defect field and inhibits defect penetration into the bulk of the deposited layer. Elasticity of the lyotropic liquid crystal acts against reorientation of the molecules under the influence of the defect field. Molecules of the deposited material are packed into lateral super molecules with a limited freedom of diffusion or motion.

A disadvantage of this method is the presence of sulfate and/or sulfite groups in the resulting layer. The presence of such hydrophilic groups interfere the electronic properties of the crystal layer. Hydrophilic groups also change the optical properties of the material.

### SUMMARY OF THE INVENT ION

The present invention provides an organic optoelectronic device which comprises a multi-layer structure and a substrate. The multi-layer structure is formed on one side of said structure. The multi-layer structure comprises a first electrode layer, a second electrode layer, and at least one organic photoelectric layer. This organic photoelectric layer is an anisotropically absorbing and electrically conducting layer. The organic photoelectric layer is comprised of rodlike suprarnolecules, which comprise at least one polycyclic organic compound with a conjugated π-system. The organic photoelectric layer has a globally ordered crystal structure with an intermolecular spacing of 3.4±0.3 Å along its polarization axis. This organic photoelectric layer also has the capability to absorb electromagnetic radiation in a predetermined spectral subrange of about 200 to 3000 nm. At least one of the first and second electrodes is transparent for the incident electromagnetic radiation to which the optoelectronic device is sensitive.

Another embodiment of the present invention is a multielement organic photosensitive optoelectronic device which comprises a system of organic photovoltaic elements and a substrate. Each element comprises a transparent cathode, at least one organic photoelectric layer, and a transparent anode. The organic photoelectric layer is an anisotropically absorbing and electrically conducting layer. The organic photoelectric layer is comprised of rodlike supramolecules, which comprise at least one polycyclic organic compound with a conjugated π-system. The organic photoelectric layer has a globally ordered crystal structure with an intermolecular spacing of 3.4±0.3 Å along the polarization axis of the layer. The organic photoelectric layer has capability to absorb an electromagnetic radiation in a predetermined spectral subrange of a wavelength range from about 200 to 3000 nm. The organic photovoltaic elements are superimposed onto each other and electrically connected in parallel. The system of organic photovoltaic elements is formed on one side of substrate.

Still another embodiment of the present invention is an organic photosensitive optoelectronic device which comprises a first electrode that serves as a cathode, a second electrode that serves as an anode, a system of organic photovoltaic subcells connected in series and separated by electron-hole recombination zones, and a substrate. Each said subcell comprises an organic photoelectric layer acting as an electron donor in contact with another organic photoelectric layer acting as an electron acceptor. At least one said photoelectric layer in at least one subcell is an anisotropically absorbing and electrically conducting layer. This photoelectric layer is comprised of rodlike supramolecules, which comprise at least one polycyclic organic compound with a conjugated π-system. The photoelectric layer has a globally ordered crystal structure with an intermolecular spacing of 3.4±0.3 Å along the polarization axis of said layer. Also this photoelectric layer has capability to absorb electromagnetic radiation in a predetermined spectral subrange of about 200 to 3000 nm. The substrate bears said electrodes and at least one said photoelectric layer. At least one of said electrodes being transparent for the incident electromagnetic radiation to which the given optoelectronic device is sensitive.

The present invention further provides a method for obtaining anisotropically absorbing and electrically conducting layers. The method comprises providing a substrate, deposition by means of Cascade Crystallization Process of at least one conjugated aromatic crystalline layer onto said substrate and application of an external action upon at least one deposited conjugated aromatic crystalline layer. Said conjugated aromatic crystalline layer is characterized by the globally ordered crystalline structure with an intermolecular spacing of 3.4±0.3 Å along its polarization axis. This layer is formed by rodlike supramolecules, which comprise at least one polycyclic organic compound with a conjugated π-system and ionogenic groups. The external action is characterized by duration, character and intensity, which are selected so as to ensure a partial removal of part of ionogenic groups from the conjugated aromatic crystalline layer while retaining the crystalline structure intact after termination of the external action.

### BRIEF DESCRIPTION OF THE DRAWINGS

A more complete assessment of the present invention and its advantages will be readily achieved as the same becomes better understood by reference to the following detailed description, considered in connection with the accompanying drawings and detailed specification, all of which forms a part of the disclosure.

FIG. 1 is a schematic diagram of an organic photosensitive optoelectronic device based on a single organic photoelectric layer structure (single-layer structure) with Schottky junction and ohmic contact, which are located on the opposite surfaces of the photoelectric layer.

FIG. 2a presents an energy band diagram of a typical Schottky junction, implementing an n-type photoelectric layer.

FIG. 2b presents an energy band diagram of a typical Schottky junction, implementing ap-type photoelectric layer.

FIG. 3a schematically depicts the layer structure of an organic photosensitive optoelectronic device with a Schottky junction, an n-type photoelectric layer, an electron transport layer, and an ohmic contact.

FIG. 3b schematically depicts a layer structure of organic photosensitive optoelectronic device with a Schottky junction, a p-type photoelectric layer, a hole transport layer, and an ohmic contact.

FIG. 4 is a schematic diagram of an organic photosensitive optoelectronic device based on a single-layer structure with Schottky junction and ohmic contact, which are located on the same surface of the photoelectric layer.

FIG. 5 schematically shows an organic photosensitive optoelectronic device based on single-layer structure with Schottky junction and ohmic contact, which are located on the same surface of the photoelectric layer and form an interdigitated system of barrier and ohmic contacts.

FIG. 6 schematically depicts the structure of an organic photosensitive optoelectronic device based on a single photoelectric layer with Schottky junction and ohmic contact located on the same surface, which also contains a phase-shifting layer (retarder) and a reflective layer.

FIG. 7 schematically depicts the structure of an organic photosensitive optoelectronic device based on a single photoelectric layer with Schottky junction, which also contains an exciton-blocking layer, a phase-shifting layer (retarder), and a reflective electrode (ohmic contact).

FIG. 8a is a schematic diagram of a double-layer organic photosensitive optoelectronic device based on contacting electron donor and electron acceptor layers forming a photoelectric heterojunction.

FIG. 8b is an energy band diagram of a double-layer organic photosensitive optoelectronic device depicted in FIG. 8a.

FIG. 9a is a schematic diagram of an organic photosensitive optoelectronic device structure comprising a photoelectric heterojunction, exciton-blocking layers, a hole transport layer, and electron transport layer, and ohmic contacts.

FIG. 9b is an energy band diagram of the organic photosensitive optoelectronic device shown in FIG. 9a.

FIG. 10 schematically depicts an organic photosensitive optoelectronic device structure comprising a conducting layer in ohmic contact with one photoelectric layer, a photoelectric heterojunction, a phase-shifting layer (retarder) and a reflective electrode (ohmic contact).

FIG. 11 schematically shows a multielement organic photosensitive optoelectronic device structure comprising a system of superimposed organic photovoltaic elements electrically connected in parallel.

FIG. 12 schematically depicts the structure of a multielement organic photosensitive optoelectronic device similar to that shown in the FIG. 12, containing an additional phase-shifting layer (retarder) and a reflective electrode (ohmic contact).

FIG. 13 schematically shows an organic photosensitive optoelectronic device structure comprising serially connected photoelectric subcells separated by electron-hole recombination zones.

FIG. 14 schematically shows an organic photosensitive optoelectronic device structure comprising a series of double-layer subcells separated by electron-hole recombination zones, a phase-shifting layer (retarder), and a reflective electrode (ohmic contact).

FIG. 15 shows the data of derivatographic analysis (the weight loss).

### DETAILED DESCRIPTION OF THE INVENTION

The general description of the present invention having been made, a further understanding can be obtained by reference to the specific preferred embodiments, which are given herein only for the purpose of illustration and are not intended to limit the scope of the appended claims.

This invention discloses some types of photosensitive optoelectronic devices comprising (1) devices converting electromagnetic radiation into electricity known as photovoltaic devices and including solar cells, (2) photoconductor cells, and (3) photodetectors. These three classes of photosensitive optoelectronic devices may be characterized according to whether a rectifying junction as defined below is present and also according to whether the device is operated with an external applied voltage, also known as a bias voltage (or simply bias).

Many organic photosensitive optoelectronic devices contain the so-called barrier contacts near which internal electric fields are generated. Such contacts are alternatively called rectifying junctions. A characteristic feature of the barrier contacts is their ability to pass electric current under direct (forward) bias and not to pass the current under reverse bias conditions. Examples of rectifying junctions are offered by the contacts between metals and organic or inorganic semiconductors with Schottky barrier formation, contacts between semiconductors possessing different conductivity types with the formation of p-n junction, and contacts between organic semiconductors of different types, one being electron acceptor and the other, electron donor, with the formation of a photoelectric heterojunction.

The rectification effect is related to the formation of an internal (built-in) electric field at the interface between two contacting materials. The internal field occupies a certain region of space in the vicinity of the interface, which is frequently called the space charge region or the active region. The depth of this region depends on the electrical properties of materials in contact, in particular, on the degree of doping and the mutual arrangement of molecular quantum energy levels (energy band diagrams). The internal fields play an important role in the operation of some organic photosensitive optoelectronic devices. As noted above, the dissociation of photogenerated excitons in organic semiconductors leads to the appearance of free mobile charge carriers, electrons and holes. The built-in electric field drives these electrons and holes in the opposite directions, so that the mobile carriers can more rapidly attain the corresponding electrodes and avoid premature recombination. Thus, the higher the built-in field strength, the stronger the photocurrent in an organic photosensitive optoelectronic device, the lower the probability of the electron-hole recombination, the smaller the leak currents in a photovoltaic device and the higher the photovoltaic conversion efficiency.

In what follows, the term “cathode” is used in the following manner. In a photosensitive optoelectronic device (e.g., in a solar cell) exposed to ambient irradiation, connected to a resistive load and not to an externally voltage source, electrons move to the cathode from the adjacent region of photoconducting material. With an applied bias voltage, electrons can move from the cathode to the adjacent photoconducting material, or vice versa, depending on the direction and magnitude of the applied voltage. For example, under forward bias conditions, a negative voltage sign is applied to the cathode. When the magnitude of the forward bias potential equals that of the internally generated potential, there will be no net current through the device. If the forward bias potential exceeds the internal potential in magnitude, there will be a current in the opposite direction relative to the nonbiased situation. In this later forward bias situation, electrons move from the cathode into the adjacent photoconducting organic layer. Under reverse bias conditions, a positive voltage sign is applied to the cathode and any electrons, which can move, do so in the same direction as in the nonbiased situation. A reverse biased device generally has little or no current flow until it is irradiated. Similarly, the term “anode” is used herein such that in a solar cell under illumination, holes move to the anode from the adjacent photoconducting material, which is equivalent to electrons moving in the opposite direction. The application of an external voltage to the device structure will alter the flow of the carriers at the anode/photoconductor interface in a complementary fashion to that described for the cathode and in a manner understood by those of ordinary skill in the art. It will be noted that, as the terms are used herein, anodes and cathodes may be electrodes or charge transfer layers. Thus, negative charge carriers (electrons) move between the cathode and the adjacent layers of a photoconducting material irrespective of the polarity of voltage applied to a given photovoltaic device. By the same token, positive charge carriers (holes) move in the space between an anode and the adjacent layers of a photoconducting material irrespective of the bias voltage polarity.

### Description of Exemplary Embodiments

In a preferred embodiment, the present invention provides an organic optoelectronic device comprising a multi-layer structure and a substrate. The multi-layer structure is formed on one side of said substrate. The multi-layer structure comprises a first electrode layer, a second electrode layer, and at least one organic photoelectric layer. This organic photoelectric layer is an anisotropically absorbing and electrically conducting layer. The organic photoelectric layer is comprised of rodlike supramolecules, which comprise at least one polycyclic organic compound with a conjugated π-system. The polycyclic organic compound can be disc-shaped. The organic photoelectric layer has a globally ordered crystal structure with an intermolecular spacing of 3.4±0.3 Å along its polarization axis. This organic photoelectric layer also has the capability to absorb electromagnetic radiation in a predetermined spectral subrange of 200 to 3000 nm. At least one of said electrodes is transparent for the incident electromagnetic radiation to which the given optoelectronic device is sensitive.

The cathode material (Al, Ca, In, Ag) usually employed in organic optoelectronic devices is characterized by low values of the electron work function, while the anode material (e.g., Au) is characterized by high values of this parameter. In solar cells and photodiodes, one contact (electrode) has to be at least partially transparent to the incident solar radiation. Semitransparent metal electrodes can be obtained when the metal (e.g., Au) film thickness does not exceed 15 to 20 nm, while nontransparent metal contacts are typically 50 to 100 nm thick. The surface resistance of a thin semitransparent layer can be significantly higher than that of a thick (50 to 100 nm) film, which noticeably increases the serial resistance of a photovoltaic device and decreases the conversion efficiency. The optical properties of such contacts significantly vary with thickness in the narrow interval from 10 to 20 nm, so that photoelectric devices with only slightly different metal contact thickness may possess incomparable characteristics.

For the above reasons, transparent electrodes in photosensitive optoelectronic devices are usually made of the so-called conducting glasses. Most widely used is a tin-doped indium oxide (indium tin oxide, ITO) representing a degenerate semiconductor comprising a mixture of In₂O₃ (90%) and SnO₂ (10%) with a bandgap width of 3.7 eV and a Fermi level between 4.5 and 4.9 eV. Because of the large bandgap, ITO does not absorb radiation of a wavelength exceeding 350 nm. This material possesses a high electric conductivity, whereby tin acts as a donor impurity rendering the resistivity very low even for ITO layers with thicknesses on the order of 100 nm. Quartz substrates covered with ITO layers are commercially available because such substrates are widely used as conducting screens in liquid crystal displays. The greater the ITO layer thickness, the lower the resistivity of this film. Typical ITO layer thickness in organic photosensitive optoelectronic devices is about 100 nm. Substrates with resistivities below 50 Ω/□ are readily available. The ability to transmit radiation does not vary significantly with the ITO layer thickness, since the material virtually does not absorb in the visible spectral range. However, interference effects may considerably influence the spectral dependence of the optical transmission coefficient. The use of very thick ITO layers (more than several hundred nanometers) is problematic, because increasing surface roughness of such thick films may lead to electric shorts in thin organic films. It should be noted that ITO films can be also used as antireflection coatings. Plasma etching can modify the surface of ITO layers. Transparent electrodes can be also made of other conducting glasses based on tin and indium oxides.

An important distinguishing feature of the present invention is the fact that the anisotropically absorbing and electrically conducting layer is made of a polycyclic organic compound with a conjugated π-system. The polycyclic organic compound can be disc-shaped. A bandgap width of 1.1 eV is known to ensure absorption of 77% of the incident solar radiation on the Earth (S. M. Sze, Physics of Semiconductor Devices (Wiley Interscience, New York, 1981). This bandgap width corresponds to inorganic semiconductor materials such as crystalline silicon. Most organic semiconductors possess bandgap widths above 2.0 eV, for which only about 30% of the incident solar radiation is absorbed in the semiconductor. This decrease in the absorbed radiation fraction significantly reduces the efficiency of organic photovoltaic devices as compared to the inorganic ones. In order to increase the conversion efficiency of the organic photosensitive optoelectronic devices, it is necessary to use the organic semiconductors with possibly small bangap width. There is an empirical rule, whereby the bandgap width of an organic semiconductor decreases with increasing conjugated π system size (see K. Petritsch, Organic Solar Cell Architectures (PhD Thesis), Cambridge and Graz, 2000). Examples of large π systems are offered by phthalocyanines and perylenes. Organic materials based on discotic molecules employed in this invention also form large π systems favoring an increase in the conversion efficiency of related organic photosensitive optoelectronic devices.

An important advantageous feature of the present invention is that the organic optoelectronic device contains at least one anisotropically absorbing and conducting layer. This layer is composed of rodlike supramolecules, which comprise at least one polycyclic organic compound with conjugated π-system and possesses a globally ordered crystal structure with an intermolecular spacing of 3.4±0.3 Å along the polarization axis of said layer. The polycyclic organic compound can be disc-shaped. The global order means that the deposition process controls the direction of the crystallographic axis (polarization axis) of the anisotropically absorbing and electrically conducting layer over the entire substrate surface. An external action applied upon formation of the anisotropically absorbing and electrically conducting layer does not disturb this global order. Thus, the anisotropically absorbing and electrically conducting layer differs from a polycrystalline layer in which a uniform crystal structure exists inside each separate grain which area is much smaller as compared to that of the substrate. The anisotropically absorbing and electrically conducting layer structure is also characterized by a nonsignificant influence of the substrate surface structure. Such a layer can be formed, if required, on the whole or on a part of the substrate surface. The global order is inherent in the anisotropically absorbing and electrically conducting layer in both cases.

The presence of a global order in the anisotropically absorbing and electrically conducting layer structure leads to an increase in the mobility of electrons and holes in this layer and, hence, to the corresponding increase in the diffusion length of photogenerated excitons as compared to that, for example, in a polycrystalline layer. Indeed, polycrystalline layers are characterized by the appearance of localized energy states in the bandgap at the grain boundaries, where periodicity of the crystal structure is broken. These states act both as the traps for mobile charge carriers and as the electron-hole recombination centers. Global order decreases concentration of defects. Another reason for an increase in the mobility of electrons and holes in the anisotropically absorbing and electrically conducting layer is that ionogenic groups, which can also act as the effective traps of charge carriers, are removed from the organic compound in the course of layer formation. This increase in the mobility of electrons and holes leads to important consequences. The first is a decrease in the serial resistance of an organic photosensitive optoelectronic device leading to an increase in the photovoltaic conversion efficiency. Another consequence of the global order in the anisotropically absorbing and electrically conducting layer is a decrease in the density of the electron-hole recombination centers, which leads to significant reduction in the recombination of both free electrons and holes and the electron-hole pairs bound in excitons. The electron-hole recombination implies that recombined charge carriers no longer participate in the photocurrent and, hence, the conversion efficiency drops. Thus, the use of globally ordered layers favors an increase in the conversion efficiency of the organic photosensitive optoelectronic devices.

A comparison of the physical principles of operation of the photosensitive optoelectronic devices based on inorganic and organic semiconductors leads to a conclusion that the photovoltaic conversion efficiency in the former case is generally much greater than that in the latter case. The main reason is that the mobile charge carriers (electrons and holes) in inorganic semiconductors are generated directly under the action of absorbed electromagnetic radiation. In contrast, the generation of free charge carriers in the organic semiconductors as considered above proceeds in several stages. The bound electron-hole pairs (excitons) produced in the first stage diffuse toward a photoelectric heterojunction and dissociate with the formation of mobile electrons and holes. From this it is clear that, given the inherently low carrier generation efficiency in the organic semiconductors, an important factor in the organic photosensitive optoelectronic devices is the possibility to optimize the semiconductor device structure so as to provide for the maximum possible efficiency.

In particular, the effective operation of the organic photosensitive optoelectronic device can be achieved only in case all photoelectric layers possess optimum thicknesses. On the one hand, it is desired that the photoelectric layer thickness would be comparable with or smaller than the diffusion length of photogenerated excitons. In this case, excitons would dissociate predominantly near the photoelectric heterojunction. On the other hand, such a small thickness of the photoelectric layer decreases the fraction of absorbed electromagnetic radiation incident upon the organic photosensitive optoelectronic device and, hence, reduces the external quantum efficiency of the device. In order to increase the absorbed electromagnetic radiation fraction, it is desired that the photoelectric layer thickness would be on the order of the effective radiation absorption length l/α, where α is the radiation absorption coefficient. In this case, almost all radiation incidents on the device will be absorbed within the photoconducting layer and will therefore contribute to the exciton production. However, as soon as the photoconducting layer thickness will exceed that of the active region, excitons will form with increased probability in the electrically neutral region far from the photoelectric heterojunction. As a result, due to a small diffusion length of excitons, the electron-hole pairs will recombine before such excitons will diffuse to enter the active region. Thus, the conversion efficiency drops with increase in the photoconducting layer thickness. Another adverse effect of increase in the photoconducting layer thickness consists in the related growth of a serial resistance of the organic photosensitive optoelectronic device, which leads to an increase in ohmic losses and a decrease in the conversion efficiency. Taking into account all the aforementioned competitive factors related to the characteristic radiation absorption length, exciton diffusion length, and resistivity of the photoelectric material, one may conclude that there are optimum photoelectric layer thicknesses providing for the maximum possible conversion efficiency of each particular organic photosensitive optoelectronic device. An important factor in reaching the maximum efficiency is the possibility of exactly reproducing the optimum thicknesses of the photoconducting layer. An important advantage of the use of disclosed anisotropically absorbing and electrically conducting layer is the possibility of controlling their thicknesses during deposition from colloidal solutions.

Owing to anisotropic properties of the photoelectric layers employed in the disclosed organic photosensitive optoelectronic devices, these devices can be used as detectors of linearly polarized electromagnetic radiation. In other words, the response of disclosed photosensitive optoelectronic devices depends on mutual orientation of an optical transmission axis of organic photoelectric layer and polarization vector of linearly polarized electromagnetic radiation.

One of the embodiments of the disclosed organic photosensitive optoelectronic device comprises a single organic photoelectric layer. The organic photoelectric layer has a front surface, which is faced to a light source, and a rear surface, which is faced to an opposite direction. In another embodiment of the disclosed organic photosensitive optoelectronic device the single organic photoelectric layer is located between two electrodes, wherein one electrode is located between a light source and said organic photoelectric layer and is a front transparent electrode, and other electrode is located behind said organic photoelectric layer and is a rear electrode.

The efficiency of an organic photosensitive optoelectronic device can be increased by allowing the incident electromagnetic radiation to doubly pass through the active photoelectric layers of the device structure. For this purpose, in one embodiment of the invention one electrode is made transparent while the other electrode represents a reflective electrode with a reflection coefficient of not less than 95% for the electromagnetic radiation entering the device structure. Herein and later we will refer these two electrodes as a transparent electrode and a reflective electrode. In addition, since at least one photoelectric layer of said organic photosensitive optoelectronic device is anisotropically absorbing, the electromagnetic radiation transmitted through this layer in one direction will be polarized. Being reflected from the reflective electrode, this polarized radiation will not be repeatedly absorbed in the anisotropic layer on the second passage. In order to avoid this, it is necessary to rotate the polarization vector 90°. Therefore, an additional retarder layer is introduced into this embodiment, the thickness and optical anisotropy of which are selected so as to ensure a 45° rotation of the polarization vector of the transmitted radiation.

In a further embodiment the rear electrode is a reflective electrode for the electromagnetic radiation incident upon the device, and the device further comprises an additional retarder layer which is located between said reflective electrode and said photoelectric layer, wherein the thickness and optical anisotropy of said retarder layer are selected so as to ensure a 45° rotation of the polarization vector of said electromagnetic radiation. There is another possible embodiment of the disclosed device, wherein a reflection coefficient of the reflective electrode is not less than 95% for the electromagnetic radiation incident upon the device.

In one embodiment the front electrode serves as a cathode and the rear electrode serves as an anode. In another embodiment the front electrode serves as an anode and the rear electrode serves as a cathode. In a further embodiment of invention the organic photosensitive optoelectronic device further comprises at least one electron transport layer situated between said organic photoelectric layer and said cathode. According to the disclosed invention, the organic photosensitive optoelectronic device further comprises at least one exciton blocking layer situated between said organic photoelectric layer and the electron transport layer.

Here, it is necessary to elucidate the term “exciton blocking layer”. The efficiency of a photovoltaic device can be increased by introducing one or several layers restricting the domain of existence of photogenerated excitons to a region in the vicinity of the photoelectric heterojunction. Such layers hinder the motion of photogenerated excitons toward electrodes where such bound electron-hole pairs can recombine at the interface between the organic semiconductor and electrode material. Thus, the exciton blocking layer limits the device volume where exciton diffusion is possible. Therefore, this layer or layers act as diffusion barriers. It should be noted that the exciton blocking layer should be sufficiently thick to fill small holes in the adjacent photoelectric layer and exclude the appearance of microscopic conducting channels (microchannels) that might form in the stage of electrode application. Thus, the exciton blocking layer provides for an additional protection of a brittle organic photoelectric layer from being damaged in the course of electrode formation.

The ability of blocking excitons is related to the fact that the LUMO-HOMO energy difference in the material of this layer is a greater than the bandgap width in the adjacent organic semiconductor layers. This implies an energetic prohibition for excitons to enter the blocking layer. While blocking excitons, this layer must allow the motion of electric charges to electrodes. For these reasons, the blocking layer material has to be selected so as to provide for the passage of charge carriers of the corresponding sign. In particular, the exciton blocking layer on the cathode side must possess a LUMO level close to (or matched with) that of the adjacent electron transport layer, so that the energy barrier for electrons would be minimum. It must be taken into account that the ability of a material to block excitons is not related to the intrinsic properties such as the LUMO-HOMO energy difference. Apparently, the material will block excitons depending on the relative values of LUMO and HOMO energies in the adjacent layers of the organic photoelectric materials. Therefore, it is impossible to indicate a priori the class of optimum materials for exciton blocking layers irrespective of the particular function of such materials in a given photovoltaic device. However, once the organic photoelectric material for the given device is selected, it is always possible to choose an appropriate exciton blocking material as well. In the preferred embodiment of the disclosed invention, an exciton blocking layer is situated between an electron acceptor layer and the cathode. A recommended material for this layer is 2,0-dimethyl-4,7-diphenyl-1,10-phenanthroline.

Such variant of embodiment of organic photosensitive optoelectronic device is possible, when device further comprises at least one hole transport layer situated between said organic photoelectric layer and said anode. Another embodiment of the organic photosensitive optoelectronic device further comprises at least one exciton blocking layer situated between said organic photoelectric layer and the hole transport layer. In another preferred embodiment, the disclosed invention comprises a first electrode formed at least on a part of front surface of the organic photoelectric layer and a second electrode formed at least on another part of said front surface of said organic photoelectric layer, wherein the first electrode serves as a cathode and the second electrode serves as an anode. In one embodiment an organic photosensitive optoelectronic device further comprises an additional retarder layer which is formed on the rear surface of said organic photoelectric layer, and an additional reflective layer which is formed on said retarder layer, wherein the thickness and optical anisotropy of said retarder layer are selected so as to ensure a 45° rotation of the polarization vector of the electromagnetic radiation incident upon the device. A reflection coefficient of the reflective layer is not less than 95% for the electromagnetic radiation incident upon the device.

Thus, an organic photovoltaic device according to the disclosed invention may contain layers effectively transferring electric charges (electrons and holes), which can be also active photoconducting layers. The terms electron transport layer and hole transport layer refer to the layers which are analogous to electrodes but differ from them in being intended for transferring mobile charge carriers from one to another layer of the given organic photosensitive optoelectronic device. In addition, such layers can be used for planarization of the surface of initially rough thick ITO electrodes (in order to prevent from the formation of shunting conducting channels through thin organic photoelectric layers). The presence of such transport and planarization layers substantially increases the useful yield of the devices.

The present invention also provides a device which further comprises two organic photoelectric layers, which form a double layer structure, wherein the first layer is an electron donor layer, and the second layer is an electron acceptor layer and contacts with the first layer, forming a photovoltaic heterojunction. The double layer structure is located between two electrodes. One electrode is located between a light source and the double layer structure and is a front transparent electrode. The other electrode is located behind the double layer structure and is a rear electrode. In one embodiment the rear electrode is a reflective electrode for the electromagnetic radiation incident upon the device, and the device further comprises an additional retarder layer which is located between said reflective electrode and said double layer structure, wherein the thickness and optical anisotropy of said retarder layer are selected so as to ensure a 45° rotation of the polarization vector of said electromagnetic radiation. The reflection coefficient of the reflective electrode is not less than 95% for the electromagnetic radiation incident upon the device structure. In one embodiment the front electrode serves as a cathode and the rear electrode serves as an anode. In another embodiment, the front electrode serves as an anode and the rear electrode serves as a cathode. According to the disclosed invention the organic photosensitive optoelectronic device may further comprise at least one electron transport layer situated between said organic photoelectric layer and said cathode. In another preferred embodiment, the disclosed invention provides an organic photosensitive optoelectronic device further comprising at least one exciton blocking layer situated between said organic photoelectric layer and the electron transport layer. In one embodiment the organic photosensitive optoelectronic device further comprises at least one hole transport layer situated between said organic photoelectric layer and said anode. Such variant of embodiment of the invention is possible, when the organic photosensitive optoelectronic device further comprises at least one exciton blocking layer situated between said organic photoelectric layer and the hole transport layer. In another embodiment, the organic photosensitive optoelectronic device comprises at least two said organic photoelectric layers. In one possible embodiment of the disclosed invention the polarization axes of the sequential organic photoelectric layers are parallel. In another embodiment, the polarization axes of the sequential organic photoelectric layers are mutually perpendicular. In one embodiment the device further comprises a protective transparent layer formed on external surface of said device. In another embodiment, the device further comprises an additional antireflection coating formed on an external surface of said device.

Yet another embodiment of the present invention represents a solar cell with Schottky barrier, based on a single-layer of an organic photoconducting material placed between metal or metal-like electrodes. For an n-type photoconductor, the metal (e.g. Au) is selected with a high electron work function, while for a p-type photoconductor, the electrodes are made of a metal (e.g. Al, Mg, or In) with a low electron work function. In this embodiment, the separation of charges (aimed in any photovoltaic device) is due to the dissociation of excitons in the space charge region at the metal/photoconductor interface. One electrode must form a barrier contact and the other—an ohmic contact. If the two electrodes are made of the same metal (or metal-like material), both contacts will be ohmic or barrier. In case when the both contacts will be ohmic no one space charge region featuring a built-in electric field is formed in the organic semiconductor. Such structures do not feature the dissociation of excitons and the separation of bound charges. If both contacts are of the barrier type and no external bias voltage is applied, the organic semiconductor contains two identical space charge regions (one at each electrode) in which the built-in electric fields are equal in magnitude and opposite in direction. In this case, said organic photosensitive optoelectronic device generates equal opposite photocurrents compensating one another. In other words, no photocurrent is developed in the absence of external bias voltage. Therefore, in the general case, the electrodes of said organic photosensitive optoelectronic device should be made of different materials. It is recommended that the charge separation would take place at one electrode, while the other would readily transmit the charge carriers. This can be achieved provided that the latter electrode forms no (or very small) potential barrier for the charge carrier transfer (such contact is characterized by very small resistance and is referred to as ohmic).

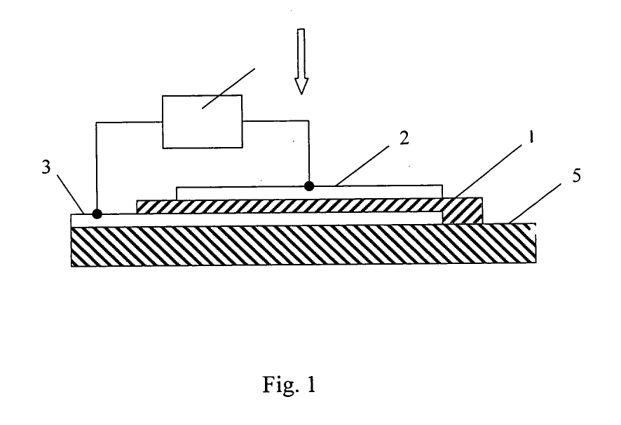

Thus, an embodiment of said organic photosensitive optoelectronic device is possible which comprises one organic photoelectric layer, wherein a rectifying Schottky barrier with one electrode is formed at least on a part of one surface of the organic photoelectric layer and an ohmic contact with the second electrode is formed at least on a part of other surface of the organic photoelectric layer. FIG. 1 presents a schematic diagram of such organic photosensitive optoelectronic device, based on photoelectric layer (1) making an Schottky barrier with one electrode (2) and an ohmic contact with another electrode (3). The entire structure is formed on a substrate (5) and the electrodes are connected to a resistive load (4).

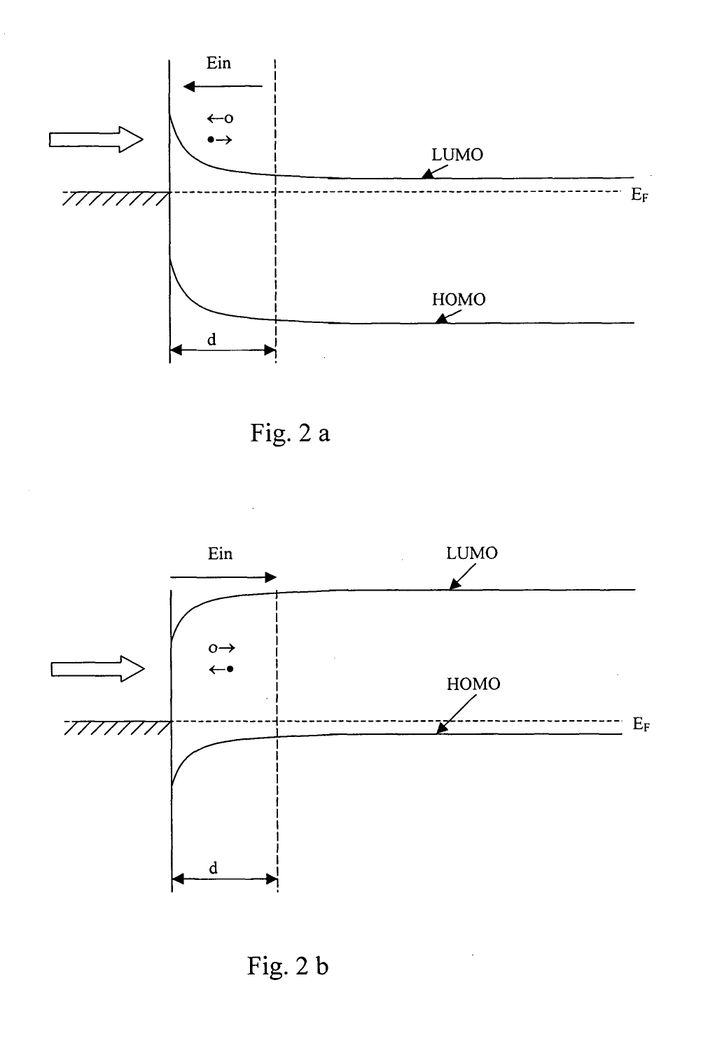

FIG. 2a presents a schematic energy band diagram of a typical Schottky junction, implementing an n-type photoelectric layer in contact with the electrode (metal or conducting glass). As can be seen, there is an active space charge region of thickness d with a built-in field of strength E_{IN} inside. This internal electric field, directed from ohmic contact to rectifying junction, produces bending of the LUMO and HOMO energy levels as depicted in this figure. FIG. 2a also indicates the directions of motion of electrons (•) and holes (◯) under the action of the built-in electric field in the case when the device is exposed to electromagnetic radiation and connected to a resistive load. In the device under consideration, based on an n-type photoelectric layer, the ohmic contact is at the cathode and the rectifying junction (Schottky barrier) is at the anode. One of these electrodes is transparent for the electromagnetic radiation in the spectral range to which the given organic photosensitive optoelectronic device is sensitive. In the case under consideration, either cathode or anode can be transparent: a transparent anode can represent a thin (10-20 nm thick) gold film, while a transparent cathode can be made of various metal-like materials such as ITO, gallium indium tin oxide (GITO), zinc indium tin oxide (ZITO), or a polymeric material such as poly (aniline) (PANI).

FIG. 2b presents a schematic energy band diagram of a typical Schottky junction, implementing a p-type photoelectric layer in contact with the electrode (metal or conducting glass). In this case, the internal electric field is directed from rectifying junction to ohmic contact, so that the rectifying junction (Schottky barrier) is at the cathode and the ohmic contact is at the anode.

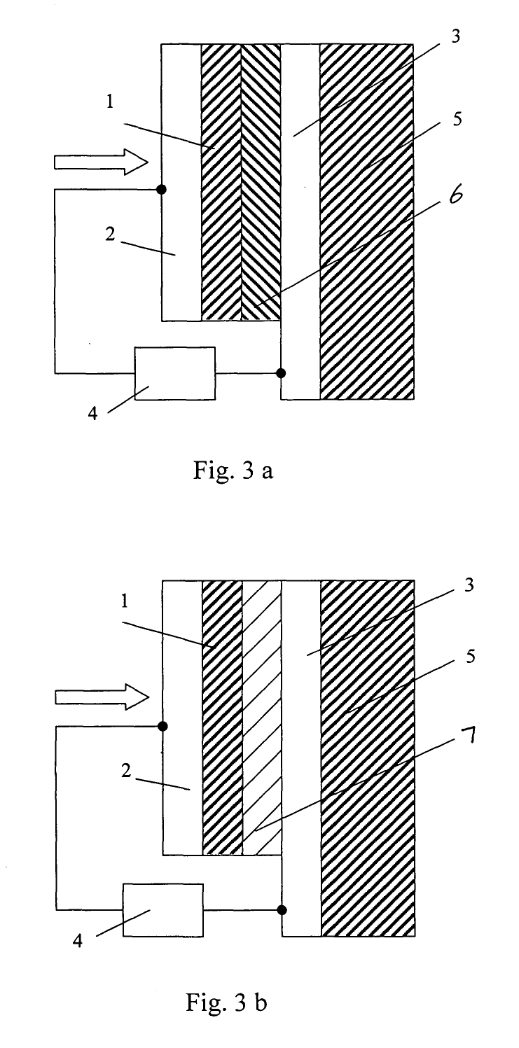

FIG. 3a schematically depicts the layer structure of an organic photosensitive optoelectronic device implementing an n-type photoelectric layer (1) forming a Schottky junction with electrode (2). This electrode serves as the anode, while electrode (3) on the opposite surface of the organic photoelectric layer forms an ohmic contact and serves as the cathode. The electron transport layer (6) situated between the photoelectric layer (1) and the cathode (3) is made of a material possessing high electron mobility and can also play the role of a planarization layer on an ITO electrode. The multilayer structure of the device is located on a substrate (5). A cathode representing a thick ITO film has rather a rough surface and sharp protrusions on this surface can damage (perforate) the thin photoelectric layer. This will lead to the formation of numerous microscopic conducting channels and a nonuniform current distribution in the junction, resulting in a premature failure of the device. Another negative consequence is a decrease in the shunting resistance and, hence, in the conversion efficiency of the organic photovoltaic device. Thus, use of an electron transport layer favors an increase in the photovoltaic conversion efficiency and in the useful yield of device production.

FIG. 3b shows another embodiment of the present invention, which is analogous to that shown in FIG. 3a but differs from it in implementing a photoelectric layer of the p-type. This structure contains a hole transport layer (7) between the photoelectric layer (1) and the anode (3). The hole transport layer, made of a material possessing a high hole mobility, favors the hole transfer from the photoelectric layer to the anode and prevents the thin organic layer from being damaged by a thick electrode. The multilayer structure of the device is located on a substrate (5).

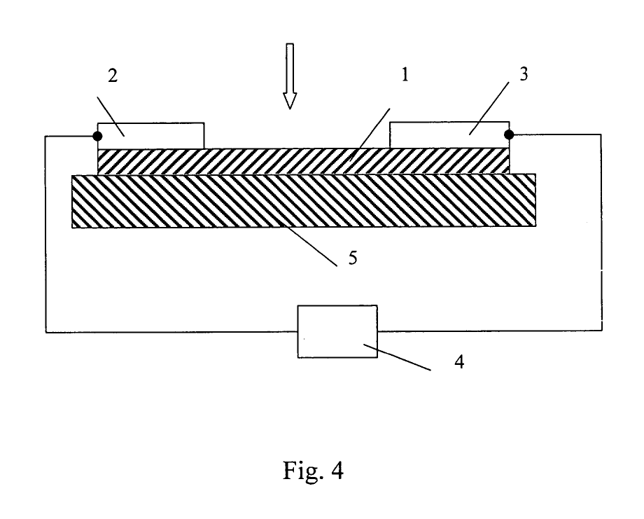

Another embodiment of the present invention, illustrated in FIG. 4, is based on a single organic photoelectric layer (1). At least a part of the one surface of said photoelectric layer contacts with the first electrode (2) to form a rectifying Schottky barrier and at least a part of the another surface is in ohmic contact with the second electrode (3); the photoelectric layer (1) is formed on a substrate (5) and the electrodes are connected to a resistive load (4).

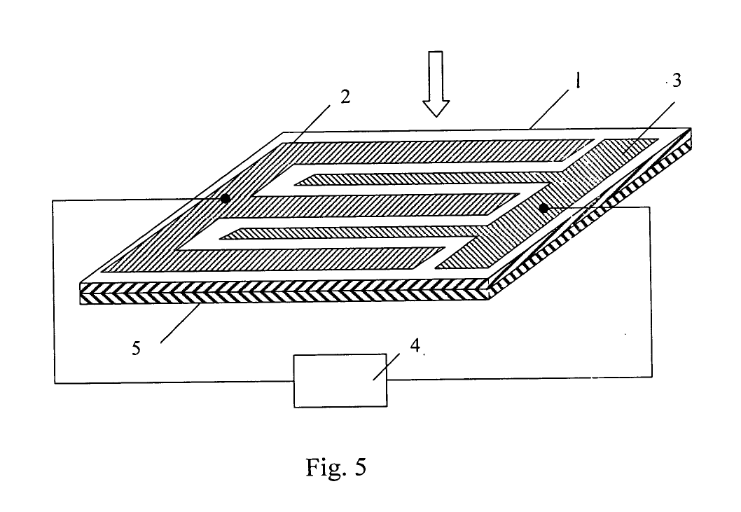

FIG. 5 shows an exemplary embodiment of the organic photosensitive optoelectronic device with an interdigitated system of electrodes. This device comprises a photoelectric layer (1) bearing a barrier (2) and ohmic (3) contacts on the same surface. The photoelectric layer is formed on a substrate (5) and the electrodes are connected to a resistive load (4).

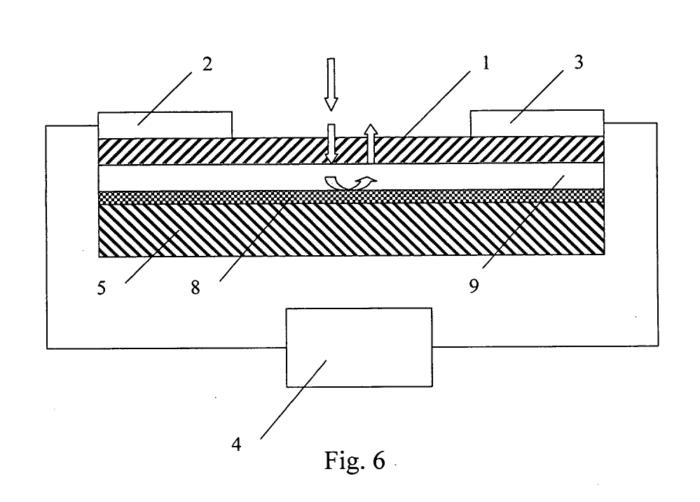

In yet another embodiment of disclosed organic photosensitive optoelectronic device illustrated in FIG. 6, one electrode (2) on a part of the one surface of a single photoelectric layer forms a Schottky junction, another electrode (3) on the same surface forms an ohmic contact, while a retarder layer (9) and an additional reflective layer (8) with a reflection coefficient of not less than 95% for the incident radiation are formed on the another surface of the photoelectric layer. The entire multilayer structure is formed on a substrate (5) and the electrodes are connected to a resistive load (4). In this structure, the incident electromagnetic radiation doubly passes through the active photoelectric layer of the device structure thus increasing the efficiency of conversion. While the electromagnetic radiation incident on layer (1) is nonpolarized, the radiation transmitter through this anisotropically absorbing layer in one direction will be partly polarized. Being reflected from the reflective layer, the radiation polarized parallel to the transmission axis of the anisotropically absorbing photoelectric layer (1) will not be repeatedly absorbed in this layer on the second passage. In order to avoid this and increase the conversion efficiency of said device, it is necessary to rotate the polarization vector 90°. To this end, an additional retarder layer (9) is introduced between a photoelectric layer (1) and a reflective layer (8). The thickness and optical anisotropy of this retarder are selected so as to ensure a 45′-rotation of the polarization vector of the transmitted radiation. Since the electromagnetic radiation doubly passes through this layer, the resulting polarization rotation amounts to 90°. Thus, the combination of retarder and reflective layer provides for a more complete use of the incident electromagnetic radiation and ensures an increase in the photovoltaic conversion efficiency of this embodiment.

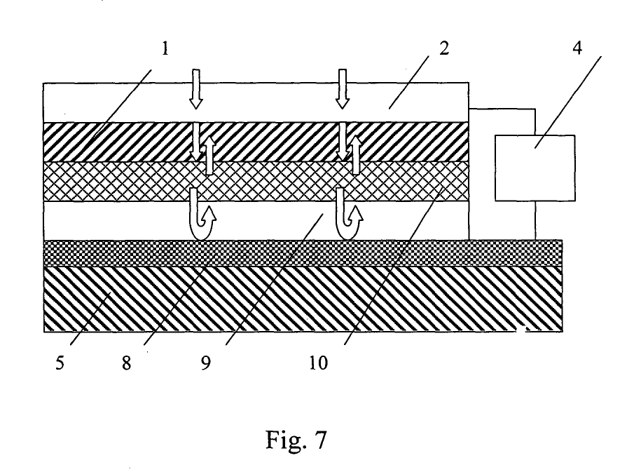

Another exemplary embodiment of the organic photosensitive optoelectronic device (FIG. 7) comprises an organic photoelectric layer (1) possessing n-type conductivity, forming a rectifying Schottky barrier with a conducting layer (2) situated on one side of said photoelectric layer. An exciton-blocking layer (10) formed on the other side of said photoelectric layer keeps the photogenerated excitons inside the active region of the device. This exciton-blocking layer simultaneously performs the function of an electron transport layer facilitating the motion of electrons toward a reflective electrode (cathode) (8). The reflective electrode (8) is required to provide that the incident radiation would be doubly transmitted through the device structure, thus increasing the conversion efficiency of the device. Since the radiation transmitted through photoelectric layer (1) becomes linearly polarized, a retarder plate (9) is placed between the exciton-blocking layer and the reflective electrode (8), the thickness and optical anisotropy of said plate being selected so as to ensure a 45°-rotation of the polarization vector of the transmitted radiation upon a single passage through the plate. A resistive load (4) is connected between the barrier contact (2) and the ohmic contact (8). The whole multilayer structure is based on a substrate (5).

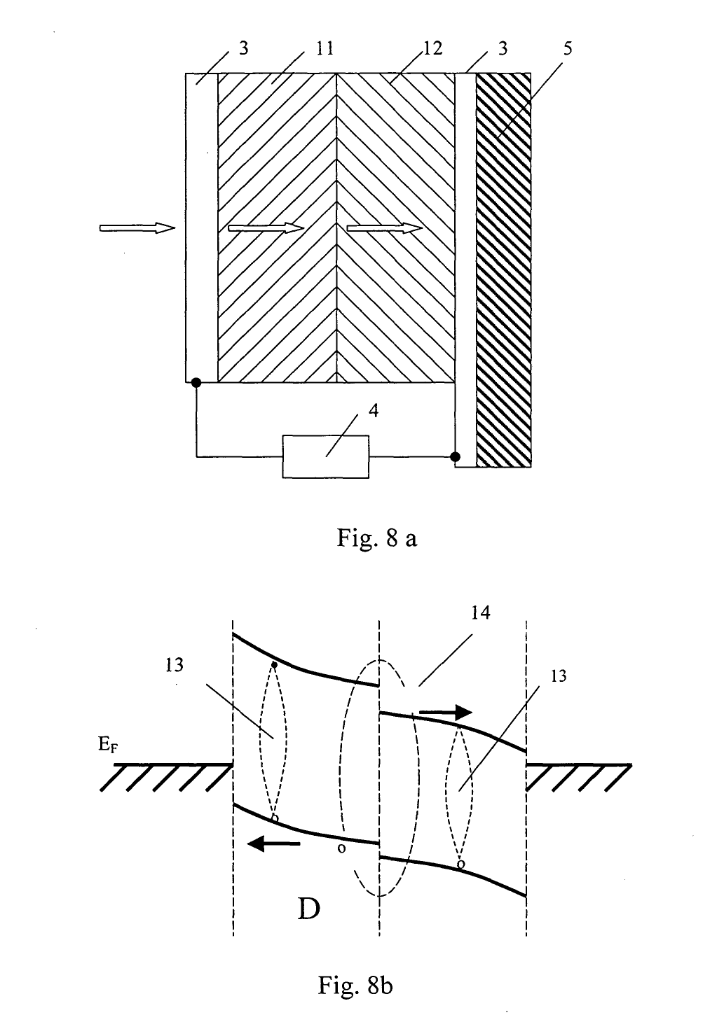

Another embodiment of the disclosed organic photosensitive optoelectronic device schematically depicted in FIG. 8a represents a two-layer (bilayer) organic photovoltaic cell in which the dissociation of excitons and the separation of bound charges proceed predominantly on the photoelectric heterojunction. The built-in electric field is determined by the LUMO-HOMO energy difference between two materials forming the heterojunction. This embodiment comprises two contacting organic photoelectric layers—an electron donor layer (11) and an electron acceptor layer (12)—forming ohmic contacts (3) with the adjacent electrodes. The entire multilayer structure is formed on a substrate (5). An energy band diagram of this double-layer organic photosensitive optoelectronic device is presented in FIG. 8b. In this structure, bound electron-hole pairs (excitons 13) are generated by the incident electromagnetic radiation in both the electron donor (D) and acceptor (A) layers, with a photoelectric heterojunction (14) formed at the interface of these layers. This region features dissociation of excitons with the formation of mobile charge carriers, electrons and holes, moving toward the cathode and anode, respectively, under the action of the built-in electric field. These separated electrons and holes move to the corresponding electrodes in different layers, namely electrons drift from the heterojunction to the cathode via the electron acceptor layer, while holes drift from the heterojunction to the anode via the electron donor layer. This property of a double-layer organic photosensitive optoelectronic structure reduces probability of the electron-hole recombination, thus increasing the photovoltaic conversion efficiency. Another advantage of the double-layer organic photosensitive optoelectronic device to a single layer counterpart is the basic possibility of using a wider wavelength range of the incident radiation. To this end, the electron donor and acceptor layers have to be made of materials possessing different absorption bands.

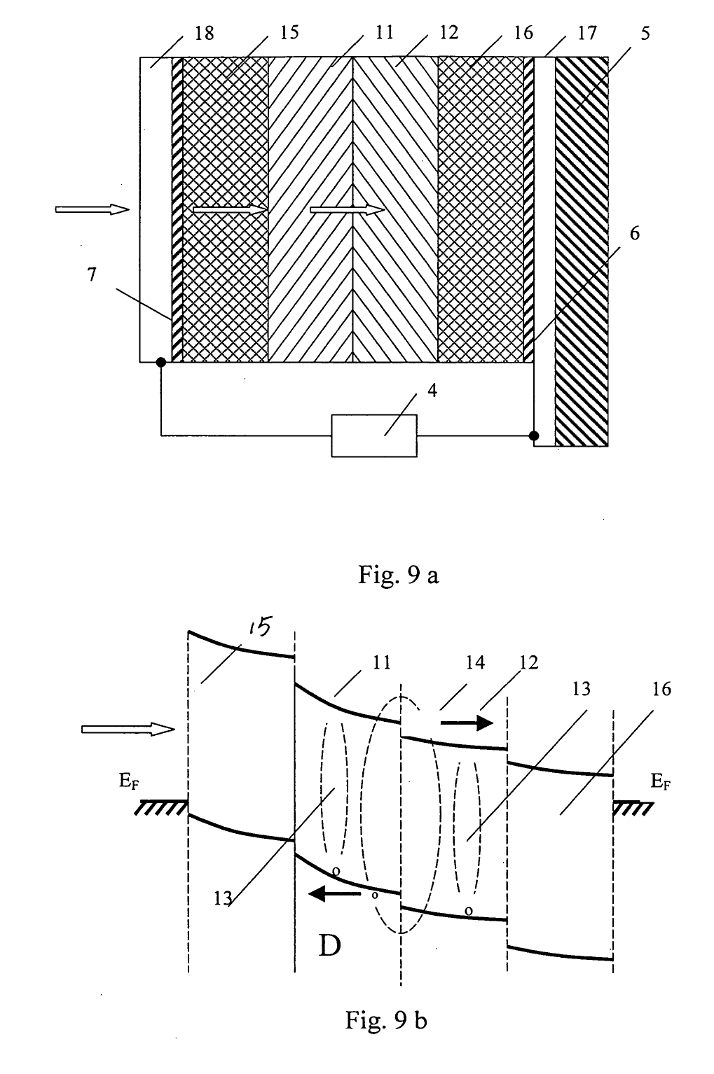

An exemplary embodiment of the organic photosensitive optoelectronic device, schematically shown in FIG. 9a, represents a modified variant of the device depicted in FIG. 8a. This modified variant comprises an electron donor layer (11) in contact with an electron acceptor layer (12), this contact representing a photoelectric heterojunction. Excitons (13) can be generated by electromagnetic radiation within both electron and donor layers. Said heterojunction (14) serves as the site where excitons exhibit dissociation to yield electrons and holes moving toward the cathode (17) and the anode (18), respectively, under the action of a built-in electric field. An exciton-blocking layer (16) formed between said electron acceptor layer (12) and the cathode (17) limits the region where photogenerated excitons can occur prior to dissociation, while not hindering the drift of electrons toward the cathode. An additional electron transport layer (6) can be formed between the exciton blocking layer (16) and the cathode (17). In the same way another exciton blocking layer (15) formed on the other side of said heterojunction between an electron donor layer (11) and the anode (18) also restricts the region where excitons occur to the vicinity of the heterojunciton, while not hindering the drift of holes toward the anode. An additional hole-transporting layer (7) can be formed between the exciton blocking layer (15) and the anode (18). The cathode (17) occurs in ohmic contact with the adjacent electron transport layer, while the anode (18) is in ohmic contact with the adjacent hole transport layer. A resistive load (4) is connected between the cathode (17) and the anode (18). The whole multilayer structure is based on a substrate (5).

FIG. 9b shows an energy band diagram of the device depicted in FIG. 9a. According to this, bound electron-hole pairs (excitons) can be generated under the action of incident electromagnetic radiation in both electron donor and acceptor layer. The boundary between the electron donor and acceptor layers represents a photoelectric heterojunction (14). The HOMO and LUMO energy levels of the exciton-blocking layer (16) and the adjacent electron acceptor layer (11) are mutually arranged so as to provide for (i) exciton blocking and (ii) electron passage to the cathode. The photogenerated excitons are blocked because the HOMO-LUMO energy difference in the exciton-blocking layer (16) is greater than the corresponding energy difference in the electron acceptor layer (12). Thus, for energetic reasons, excitons generated in the electron acceptor layer (12) cannot enter the exciton blocking layer (16) possessing a greater HOMO-LUMO energy difference. As can be seen from FIG. 9b, the LUMO of the exciton-blocking layer (16) lies below the LUMO level of the electron acceptor layer (12) and, hence, electrons can freely move toward the cathode. Analogous considerations are valid for the electron donor layer (11) and the exciton blocking layer (15), thereby excitons are also blocked while holes can freely drift toward the anode.

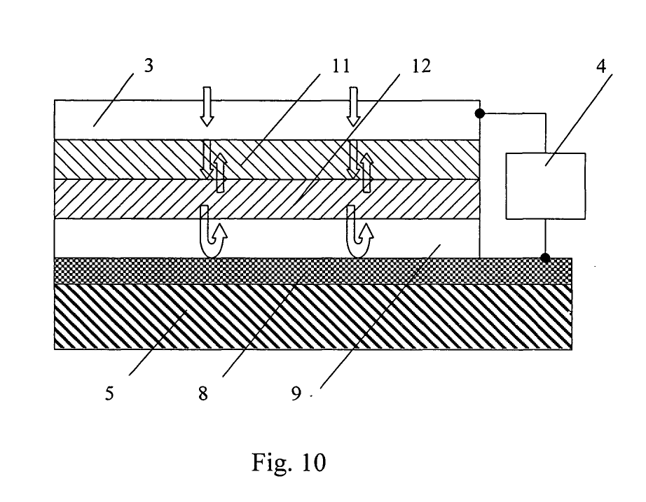

Another exemplary embodiment of the organic photosensitive optoelectronic device is schematically depicted in FIG. 10. This device also comprises an electron donor layer (11) in contact with an electron acceptor layer (12), this contact representing a photoelectric heterojunction. In order to increase the efficiency of conversion, the device is additionally provided with a reflective electrode (8) in ohmic contact with the retarder (9) the thickness and optical anisotropy of which are selected so as to ensure a 45° rotation of the polarization vector of the transmitted radiation upon a single passage through the plate. A resistive load (4) is connected between the ohmic contacts (3) and the reflective electrode (8). The whole multilayer structure is based on a substrate (5).

There is another embodiment of the disclosed organic photosensitive optoelectronic device, wherein a protective transparent layer is formed on at least one external surface of said device.

In still another embodiment of the disclosed organic photosensitive optoelectronic device, an additional antireflection coating is formed on at least one external surface of said device.

Another embodiment of the present invention is a multielement organic photosensitive optoelectronic device comprising a system of organic photovoltaic elements and a substrate. Each element comprises a transparent cathode, at least one organic photoelectric layer, and a transparent anode. The organic photoelectric layer is ananisotropically absorbing and electrically conducting layer. Said layer is comprised of rodlike supramolecules, which comprise at least one polycyclic organic compound with a conjugated π-system. The polycyclic organic compound can be disc-shaped. This layer has a globally ordered crystal structure with an intermolecular spacing of 3.4±0.3 Å along the polarization axis of said layer. The organic photoelectric layer has capability to absorb an electromagnetic radiation in a predetermined spectral subrange of a wavelength range from 200 to 3000 nm. The organic photovoltaic elements are superimposed onto each other and electrically connected in parallel. The said system of organic photovoltaic elements is formed on one side of substrate.

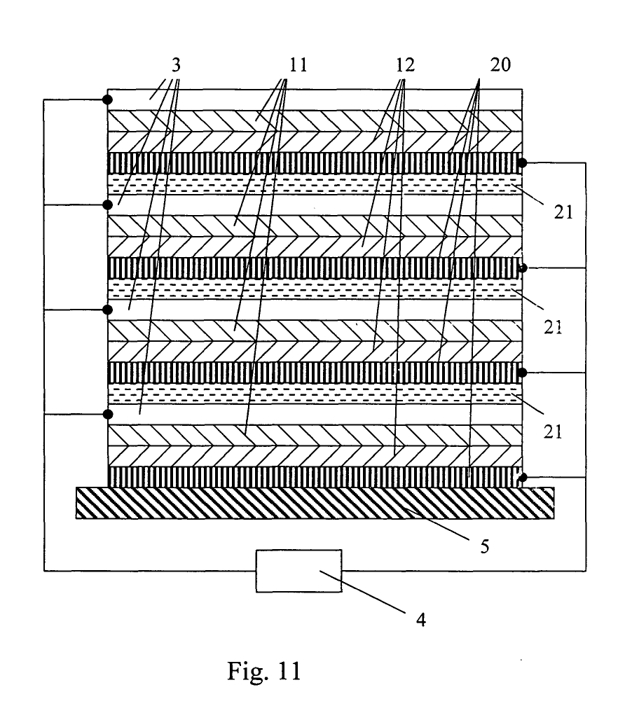

FIG. 11 shows an exemplary variant of the disclosed multielement organic photosensitive optoelectronic device. Each photovoltaic element of this device contains an electron donor layer (11) contacting and electron acceptor layer (12) to form a photoelectric heterojunction. The electron donor layer (11) is in ohmic contact with an electrode (3), while an electron acceptor layer (12) is in ohmic contact with another electrode (20). All electrodes (3) in each photovoltaic element are electrically connected to one another and to a resistive load (4). The opposite electrodes (20) of the photovoltaic elements are also connected to one another and to the resistive load. All said electrodes are made of materials transparent for the electromagnetic radiation to which the given multielement organic photosensitive optoelectronic device is sensitive. All organic photovoltaic elements are electrically isolated from each other by insulating layers (21), which are transparent for the said electromagnetic radiation. The whole multilayer structure is based on substrate (5).

In one exemplary embodiment of the multielement photosensitive optoelectronic device, said organic photovoltaic elements are selected so to have capability to absorb an electromagnetic radiation in predetermined spectral subranges of 200 to 3000 nm.

In yet another exemplary embodiment of the multielement photosensitive optoelectronic device further comprises a transparent isolating layer positioned between said organic photovoltaic elements. Thus each organic photovoltaic element is isolated from the neighboring elements by a transparent insulating layer.

Another preferred embodiment of the present invention is a multielement organic photosensitive optoelectronic device formed on a substrate transparent for the incident electromagnetic radiation. The device further comprises an additional retarder layer located on the organic photovoltaic element most distant from said substrate. A reflective layer is located on said retarder layer, wherein the thickness and optical anisotropy of said retarder layer are selected so as to provide for a 45° rotation of the polarization vector of said electromagnetic radiation. The presence of the reflective layer allows the incident radiation to be doubly used in order to increase the photovoltaic conversion efficiency. The retarder provides for a 90° rotation of the polarization vector of reflected radiation thus ensuring the absorption of both orthogonal polarization components.

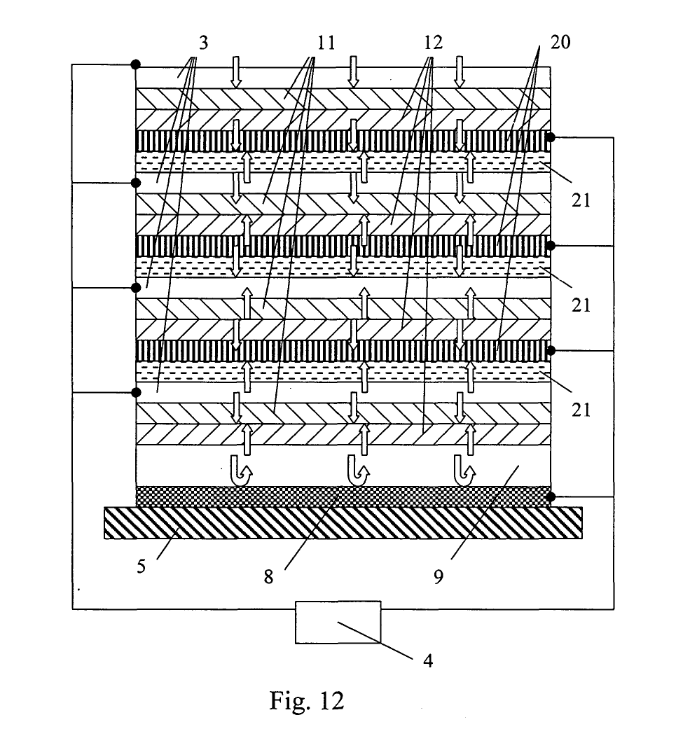

Another embodiment of the multielement organic photosensitive optoelectronic device (see FIG. 12) comprises an additional reflective layer (8) located on said substrate (5); and an additional retarder layer (9) situated between said additional reflective layer and the organic photovoltaic element closest to said substrate, wherein the thickness and optical anisotropy of said retarder are selected so as to provide for a 45° rotation of the polarization vector of the electromagnetic radiation incident upon the device. A reflection coefficient of the reflective layer is not less than 95% for the electromagnetic radiation incident upon the device structure.

Yet another embodiment of the multielement organic photosensitive optoelectronic device is possible, wherein said substrate represents a reflector, wherein a reflection coefficient is not less than 95% for the incident electromagnetic radiation; and the device further comprises an additional retarder layer situated between said substrate and the closest photovoltaic element, the thickness and optical anisotropy of said retarder layer are selected so as to provide for a 45° rotation of the polarization vector of said electromagnetic radiation.

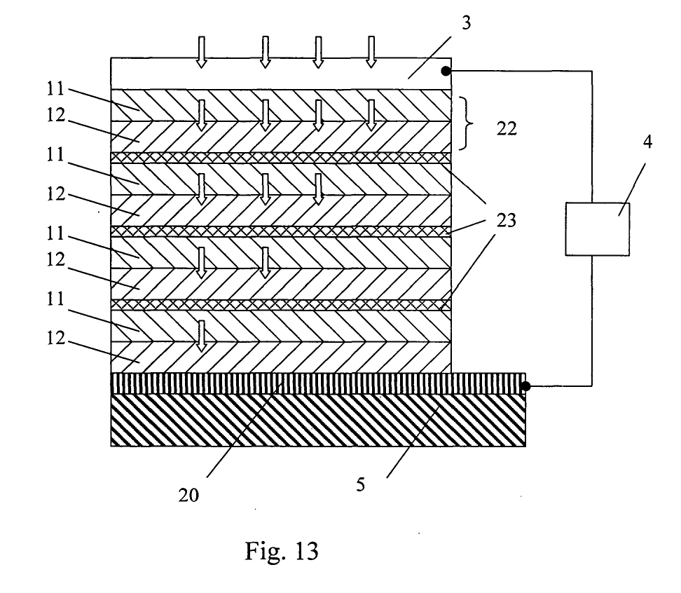

Still another embodiment of the present invention is an organic photosensitive optoelectronic device (see FIG. 13) comprising a first electrode that serves as a cathode (20), a second electrode that serves as an anode (3), a system of organic photovoltaic subcells (22) connected in series and separated by electron-hole recombination zones (23), and a substrate (5). Each said subcell comprises an organic photoelectric layer (11) acting as an electron donor (D-layer) in contact with another organic photoelectric layer (12) acting as an electron acceptor (A-layer). At least one said photoelectric layer in at least one subcell is an anisotropically absorbing and electrically conducting layer. This layer is comprised of rodlike supramolecules, which comprise at least one polycyclic organic compound with a conjugated π-system. The polycyclic organic compound can be disc-shaped. The said layer has a globally ordered crystal structure with an intermolecular spacing of 3.4±0.3 Å along the polarization axis of said layer. Also this layer has capability to absorb electromagnetic radiation in a predetermined spectral subrange of 200 to 3000 nm. The substrate bears said electrodes and at least one said photoelectric layer. At least one of said electrodes being transparent for the incident electromagnetic radiation to which the given optoelectronic device is sensitive.

It is desirable to explain distinction between element and subcell. The element has all parts, necessary for operation: a transparent cathode, at least one organic photoelectric layer, and a transparent anode. The separate element can operate independently. The subcell has no electrodes and consequently cannot operate independently. The subcell can operate as the component of more complicated devices.

The two said layers form a heterojunction. In the sequence of double layers (subcells) under consideration, the heterojunctions formed, for example, between D-layer of the first subcell and A-layer of the second subcell hinder normal operation of the photosensitive optoelectronic device. In order to prevent the formation of such heterojunctions, additional thin (5-20 Å) metal interlayers are formed between said subcells. Such a layer creates an electron-hole recombination zone that provides a space for the recombination of electrons approaching from the first subcell and holes arriving from the second subcell. A photovoltaic device comprised of several such subcells electrically connected in series represents a high-voltage unit. The donor and acceptor materials forming heterojunctions can be either the same in all elements or the D- and A-layers can be different in various subcells of the same device.

An increase in the thickness of photoelectric layers leads to the growth of a serial resistance of the organic photosensitive optoelectronic device, which results in an increase in ohmic losses and a decrease in the conversion efficiency. Another negative consequence of increasing photoelectric layer thickness is the increase in the probability for excitons to form far from the built-in electric field at the D-A interface where effective dissociation of excitons (i.e., charge separation) takes place. As a result, the number of electron-hole recombination events increases and the conversion efficiency drops. In multilayer photovoltaic devices, the photoconducting layers should be very thin. Taking into account the aforementioned competitive factors related to the characteristic radiation absorption length, exciton diffusion length, exciton production efficiency, and resistivity of the photoelectric material, it is possible to select optimum photoelectric layer thicknesses providing for the maximum possible conversion efficiency of each particular organic photosensitive optoelectronic device. The exciton diffusion length being small and the resistivity of photoelectric materials being rather large, the optimum device thicknesses are typically very small. Since the light absorption length is large, this results in decreasing overall device efficiency because only a small fraction of the incident light is effectively absorbed. In order to increase the quantum efficiency of each individual element, it is possible to increase the thickness of photoelectric layers so as to increase the absorbed fraction of the incident electromagnetic radiation. However, the efficiency will cease to grow as soon as the layer thickness will exceed 2-3 diffusion lengths of photogenerated excitons. On the other hand, if the thickness of an individual element is smaller than the active layer thickness, the absorption drops even more rapidly and the efficiency decreases linearly with the photoelectric layer thickness.

The condition of balance for the currents generated by each subcell in a photovoltaic device (the values of currents generated by each said subcell are approximately equal) puts limitation to the maximum number of subcells in such devices. In a sequence of layers, each subsequent subcell receives decreasing fraction of the incident electromagnetic radiation because a part of it is absorbed in the preceding layers. For this reason, each next layer has to be thicker than the preceding one, so as to generate the same number of excitons. As was demonstrated above, the thickness of the last subcell in the sequence cannot be increased arbitrarily. This poses a natural limit on the number of stacked subcells.

Each subcell in a multilayer photovoltaic device contains acceptor and donor layers in contact, forming heterojunctions. These layers must possess possible large diffusion length of the photogenerated excitons. From this standpoint, preferred materials for the photoelectric layers are organic compounds capable of forming rodlike supramolecules, in particular, compounds with disc-shaped organic molecules and aromatic nuclei. Potential acceptor materials are perylenes, naphthalenes, fullerenes, and nanotubes. Another advantageous acceptor material is 3,4,9,10-perylenetetracarboxylic bisimidazole (PTCBI). The contact of acceptor and donor layers forms a heterojunction featuring a built-in electric field at the interface. Promising donor materials are phthalocyanines, purpurins, and their derivatives.

Individual photoelectric subcells can be separated by the regions of effective electron-hole recombination. Such a region can represent a thin metal layer with a thickness below 20 Å, most favorably about 5 Å. This thickness must be selected such that the layer would be transparent for the electromagnetic radiation to which the photovoltaic device is sensitive, so that the incident radiation would reach the last photoelectric subcells in the stack. The electron-hole recombination, layers can be made of Ag, Li, LiF, Al, Ti, and Sn. Alternatively, the electron-hole recombination zone can represent the layer of a material with high concentration of recombination centers. In particular, such centers can represent defects related to violation of the structural periodicity at the boundaries between layers. It should be noted that such layers must be also sufficiently thin and transparent, so that the incident radiation would reach the last photoelectric subcell in the stack.

A special detailed consideration and description are now devoted to electrodes employed in photovoltaic devices. The term “electrode” refers to conducting layers that serve to deliver the produced electric energy to an external circuit or to supply a bias voltage to the photoelectric layers. Thus, each electrode represents essentially an interface between the active photoconducting region of a photovoltaic device and the external resistive load or an energy storage unit. At least one electrode must possess a minimum absorption and minimum reflection of the electromagnetic radiation incident on a given photovoltaic device. In other words, this electrode must be transparent for the incident electromagnetic radiation (light) to which the given photovoltaic device is sensitive. The opposite electrode can be either transparent or nontransparent, or it can be reflective electrode. In the latter case, as part of the radiation not absorbed in the photoelectric layers will be reflected and transmitted through the same photoelectric layers once again in the reverse direction. Therefore, a reflecting electrode provides for an increase in the efficiency of photovoltaic device. An electrode is called in a certain wavelength range if more than 50% of the incident radiation in this range can pass through this electrode without absorption. In other words, a transparent electrode transmits at least 50% of the incident radiation. At the same time, an electrode transmitting less than 50% of the incident radiation is referred to as semitransparent.

Electrodes can be made either of metals (magnesium, gold, solver, aluminum) and related alloys (e.g., Mg—Ag) or of metal-like transparent materials such as indium tin oxide (ITO), gallium indium tin oxide (GITO), or zinc indium tin oxide (ZITO). Most widely used ITO represents a highly doped n-type semiconductor with an optical bandgap width of 3.2 eV. Another transparent conducting material for electrodes is poly(aniline) (PANI) and its derivatives.

One exemplary embodiment is an organic photosensitive optoelectronic device with an exciton blocking layer is situated between the electron acceptor layer and the cathode. This arrangement of the exciton blocking allows the photogenerated excitons to be concentrated in the vicinity of the heterojunction, thus increasing the photovoltaic conversion efficiency.

Another exemplary embodiment is the organic photosensitive optoelectronic device with subcells connected in series, in which an electron-hole recombination zone is a semitransparent metal layer.

Another exemplary embodiment is the organic photosensitive optoelectronic device with an electron-hole recombination zone representing a region of electrically active defects.

Another exemplary embodiment is the organic photosensitive optoelectronic device with subcells connected in series, wherein said subcells are selected to have ability to absorb an electromagnetic radiation in predetermined spectral subranges.

Another exemplary embodiment is the organic photosensitive optoelectronic device with subcells connected in series, wherein the absorb ability is controlled by selecting the type of organic photovoltaic materials for each of said subcells.

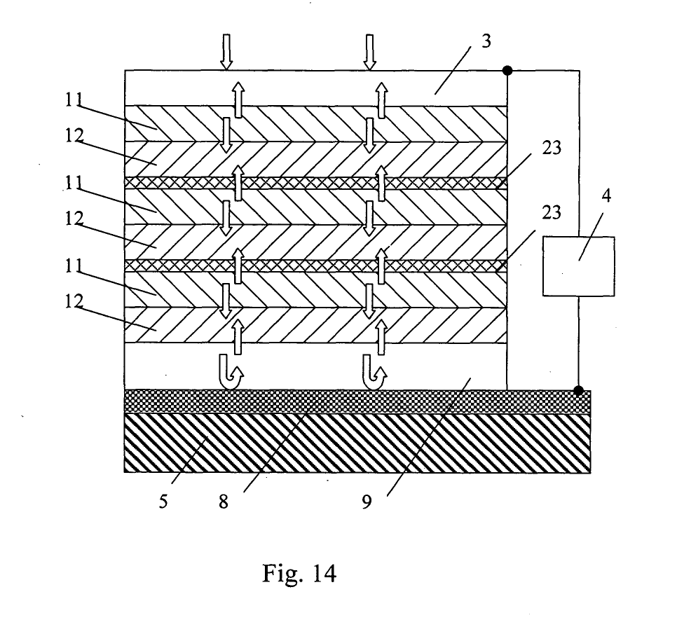

Still another exemplary embodiment is the organic photosensitive optoelectronic device (see FIG. 14), wherein one electrode (3) is made transparent for the electromagnetic radiation incident onto the device, while the other electrode (8) represents a reflective layer with a reflection coefficient of not less than 95% for the electromagnetic radiation entering the device; and said device comprises an additional retarder layer (9) introduced between said reflective layer (8) and said system of subcells, wherein the thickness and optical anisotropy of retarder layer are selected so as to ensure a 45° rotation of the polarization vector of said electromagnetic radiation.

Another aspect of the present invention provides a method for obtaining anisotropically absorbing and electrically conducting layers. A method for obtaining of an anisotropically absorbing and electrically conducting layer comprises providing a substrate, deposition by means of Cascade Crystallization Process of at least one conjugated aromatic crystalline layer onto said substrate and application of an external action upon at least one deposited conjugated aromatic crystalline layer. Said conjugated aromatic crystalline layer is characterized by the globally ordered crystalline structure with intermolecular spacing of 3.4±0.3 Å along its polarization axis. This layer is formed by rodlike supramolecules, which comprise at least one polycyclic organic compound with conjugated π-system and ionogenic groups. The polycyclic organic compound can be disc-shaped. The external action is characterized by duration, character and intensity, which are selected so as to ensure a partial removal of part of ionogenic groups from the conjugated aromatic crystalline layer while retaining the crystalline structure intact after termination of the external action.

There is a known method for obtaining anisotropically absorbing and conducting conjugated aromatic crystalline layers using a lyotropic liquid crystal of at least one organic compound [see U.S. Pat. Nos. 5,739,296 and 6,049,428 and the following publications: P. Lazarev, et al., X-ray Diffraction by Large Area Organic Crystalline Nano-Films, Molecular Materials, 14 (4), 303-311 (2001); Y. Bobrov, Spectral Properties of Thin Crystal Film Polarizers, Molecular Materials, 14 (3), 191-203 (2001)]. The method is not too complicated and economically effective, ensures a high degree of anisotropy and crystallinity of the layers, offers the possibility of obtaining thin crystal films of arbitrary shape (including multilayer coatings on curvilinear surfaces), and is ecologically safe and labor and energy consuming. Using said known method, it is also possible to obtain single crystal films.

This known method for obtaining an anisotropically absorbing conjugated aromatic crystalline layer, referred to below as Cascade Crystallization Process, is characterized by the following sequence of technological operations:

(1) chemical modification of the target compound;

(2) lyotropic liquid crystal formation;

(3) application of a lyotropic liquid crystal of at least one organic compound onto a substrate;

(4) external liquefying action upon the lyotropic liquid crystal in order to decrease its viscosity;

(5) external aligning action upon the lyotropic liquid crystal in order to impart a predominant orientation to particles of the colloidal solution;

(6) termination of the external liquefying action and/or application of an additional external action so as to restore the lyotropic liquid crystal viscosity on at least the initial level;

(7) drying.

On accomplishing the above operations, Cascade Crystallization Process yields anisotropically absorbing conjugated aromatic crystalline layers with an intermolecular spacing of 3.4±0.3 Å in the direction of the polarization axis.

According to the disclosed method, the ionogenic groups are sulfonic, sulfate or sulfite groups or other ionogenic (hydrophilic) groups (e.g., COO—, PO₄—, cation groups, carboxy groups, etc.) used for imparting amphiphilic properties to the initial organic compounds.

The external action on the anisotropically absorbing conjugated aromatic crystalline layer according to said method is realized by the local or complete heating of the conjugated aromatic crystalline layer up to the pyrolysis temperature. The pyrolysis temperature is characteristic of every organic compound and should be determined experimentally for each individual substance. In our case, by pyrolysis temperature we mean the temperature of rupture of the bonds and breaking off the ionogenic groups, for example, sulfonic or sulfate and/or sulfite groups, sulfate and/or sulfite groups or any other ionogenic (hydrophilic) groups (for example, COO—, PO₄—, cationic groups, carboxyl groups and others) used for imparting amphiphilic properties to the initial organic compounds. More precisely, the temperature of pyrolysis can be defined on the basis of data of derivatographic analysis. The derivatographic analysis or the analysis of temperature dependence of weight loss of organic compound sample at deleting from them the sulfonic, sulfate or sulfite groups has shown that pyrolysis temperature in this case is in the range between 330° C. and 350° C. According to said method, the heating of an anisotropically absorbing conjugated aromatic crystalline layer can be realized in different ways, for example, using concentric electrical heaters and/or electromagnetic radiation, and/or a resistive heater, and/or alternating electric or magnetic field, and/or a flow of heated liquid or gas. The heating can be effected both from the side of the substrate and from the side of the conjugated aromatic crystalline layer. Simultaneous heating from both sides is possible as well.

It should be noted that pyrolysis of an anisotropically absorbing conjugated aromatic crystalline layer increases its mechanical hardness and improves the adhesion of the layer to the substrate. Besides the deleting of ionogenic groups diminishes a solubility of conjugated aromatic crystalline layers in polar solvents, in particular the solubility in water.

The removal of ionogenic groups, in particular-sulfonic or sulfate and/or sulfite groups can be performed by an external action carried out, on at least part of the optically anisotropic conjugated aromatic crystalline layer, using microwave and/or laser radiation. The frequency, intensity, and the duration of said external action are selected from the condition of deleting of part of all ionogenic groups while preserving crystalline structure of the layer. The radiation frequency (or the corresponding photon energy) is selected so as to be in resonance with at least one absorption band of the organic compound (the energy of binding of the ionogenic groups). The radiation frequency (photon energy) has to be experimentally selected for each individual organic compound so as to ensure that the removal of the ionogenic (hydrophilic) groups would not be accompanied by the rupture of other bonds in the initial organic substances. Thus, the frequency, the intensity, and the duration of irradiation must be selected so as to provide for the removal of sulfonic or sulfate and/or sulfite groups or any other ionogenic (hydrophilic) groups (for example, COO—, PO4—, cation groups, carboxy groups, etc.) used to impart amphiphilic properties to the initial organic material.

It should be noted that the aforementioned ionogenic groups, in particular-sulfonic or sulfate and/or sulfite groups, are extremely effective traps for the mobile charge carriers (electrons and/or holes) in the material of the anisotropically absorbing and conducting layer. For this reason, removal of these groups leads to an increase in the density and mobility of carriers (electrons and/or holes) and, hence, in the electric conductivity of the anisotropically absorbing layer.

The external action upon the conjugated aromatic crystalline layer is performed in a buffer gas atmosphere. The buffer gas can represent an inert gas (He, Ar, Xe) or some other nonreactive gas such as nitrogen, CO2, or low-molecular-weight fluorinated hydrocarbons. This list only gives some examples, by no means restricting the selection of a buffer gas: other gases and gas mixtures can be used as well.

There is yet another variant of said method, whereby the external action is performed by local or complete heating of said anisotropically absorbing conjugated aromatic crystalline layer up to a temperature of pyrolysis, which is determined from the experimental data.

In one more variant of said method, the external action is performed by treating at least part of said conjugated aromatic crystalline layer by microwave and/or laser radiation, the frequency of which is in resonance with at least one absorption band of the initial organic substance.

There is yet another variant of said method, whereby the removal part of ionogenic groups is in the range between 45% and 95% from all ionogenic groups which are present in conjugated aromatic crystalline layer before external action.

Still there is an embodiment of said method, wherein the organic compound comprises at least one aromatic compound with the general structural formula {R}(F)ₙ, where R is a polycyclic organic compound with conjugated π-systems, the structure of which contains one or more ionogenic groups, either like or unlike, ensuring the solubility in polar solvents for the formation of a lyotropic liquid crystal phase; F are modifying functional groups; and n is the number of functional groups.

### EXAMPLE 1

An organic photosensitive optoelectronic device based on a lyotropic liquid crystal formed from an organic compound the molecules of which possess a disk shape and contain at least one ionogenic (hydrophilic) group providing the solubility of the organic substance in polar solvents for forming supramolecular complexes.

A glass plate with a thickness of 0.5 mm is used as a substrate. The substrate is covered by a thin layer of indium tin oxide (ITO) formed by a spin coating technique. The ITO layer thickness was typically within 500-800 Å. In the example under consideration, the ITO layer is the anode. It was also possible to use other materials for the anode formation. It is important to note that this material should possess a high electron work function. An important property of the ITO layer is transparency to the electromagnetic radiation employed. Therefore, the light incident on the device passes through the transparent ITO layer and the transparent substrate. An anisotropic crystal layer was formed on the ITO layer.

Let us consider an example of manufacturing anisotropic crystal layers from a lyotropic liquid crystal based on an organic dye belonging to indanthrone sulfonates. Such films are used, for example, as active photoelectric layers. A 9.5% aqueous solution of indanthrone sulfonate was used to form a hexagonal liquid crystal phase at room temperature. This dye forms supramolecular complexes in solution, these complexes being the basis of the crystal structure of the photovoltaic layer. Upon cleaning the ITO surface, the initial paste was applied by method of spinning or smearing. Both methods provide approximately the same results for the given material.

Then, the lyotropic liquid crystal was subjected to an external action aimed at decreasing the liquid crystal viscosity so as to facilitate its subsequent orientation. As a result, the applied composition forms a nematic phase or a mixture of the nematic and hexagonal phases. The viscosity of the system decreased from 1780 MPa/s to 250 MPa/s. Under the conditions of preliminarily reduced viscosity of the system, a high-qualitative anisotropic crystal layer was obtained.

For the external diluting action used in the given example, heating of the applied layer from the side of the substrate holder was preferred. The substrate holder was heated so as to provide that the temperature of the applied layer of the indanthrone sulfonate paste would be 56° C. However, good results were also achieved through heating the applied layer by the electromagnetic radiation, or by of other means. A special variant of the diluting action is the use of a heated Mayer rod for realization of the local decrease in viscosity with simultaneous orientation of the applied layer.

The following operation was the process of orientation of supramolecules of the lyotropic liquid crystal. For the specified external orientation action, various orientating tools could be used. In the given example, the orienting cylindrical Mayer rod No. 4 was used with a wire wound around it that determined the thickness of the applied wet layer (9.5 mm). During the orienting treatment, the speed of the moving Mayer rod was 13 mm/sec. A shear strain arising during the Mayer rod operation resulted in additional reduction in the system viscosity. After termination the orientation stage, heating of the substrate holder was switched off and the heated Mayer rod was removed.

The following operation for the formation of an anisotropic crystal layer was drying. Preferably, the solvent has to be removed slowly so that the oriented structure of the layer formed in the preceding stage would not be disturbed. In the described example, the drying was carried out at room temperature and a relative humidity of 60%.

As a result, an anisotropic crystal layer with a thickness of 0.3-0.4 microns having a high degree of optical anisotropy was obtained: the dichroic ratio was Kd=28 at a transmission of T=40% (for the traditional method, Kd does not exceed 20), with a good reproducibility of the parameters both over the surface of layer and from one to another group of samples. Perfection of the crystal structure of the resulting anisotropic crystal layers was estimated by optical methods and X-ray diffractometry. The X-ray analysis of the anisotropic crystal layers showed that the layer formed as a result of the above technological operations had an intermolecular spacing of 3.4±0.3 Å in the direction of one of the crystallographic axes.

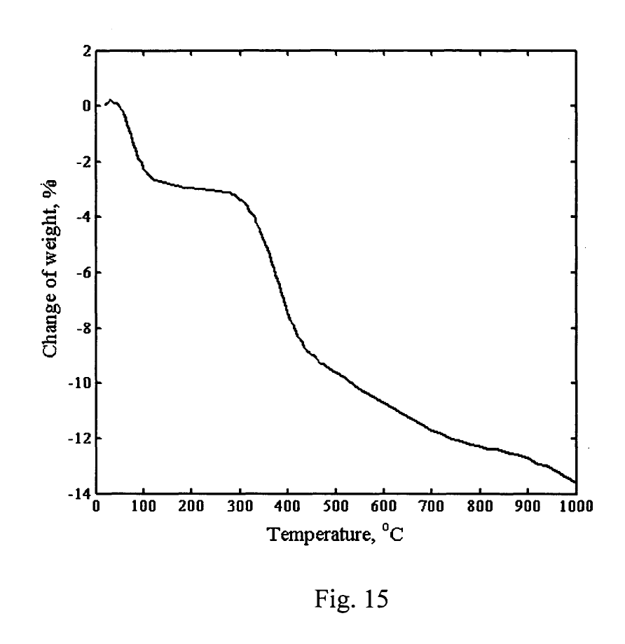

Finally, an external action was applied to the anisotropic crystal layer so as to remove ionogenic groups from the material, while retaining the crystal structure of the layer after termination of this external action. The duration, the character, and the intensity of this external action were selected so as to ensure the removal of part of all ionogenic groups from the anisotropic crystal layer with preservation of the initial crystal structure of the layer. In the initial organic substance, both sulfonic or sulfate and/or sulfite groups and any other ionogenic (hydrophilic) groups (for example, COO⁻, PO₄⁻, cation groups, carboxy-groups and others) were present which provided amphiphilic properties of the initial composition. In this example, the external action on the anisotropic crystal layer was provided by local heating of the anisotropic crystal layer to the temperature of pyrolysis, which is determined by the experimental data of the derivatographic analyses. The pyrolysis temperature is characteristic of every organic compound and should be determined experimentally for each individual organic compound and ionogenic groups. The data of derivatographic analyses (the weight loss) are shown in FIG. 15. It is visible in FIG. 15 that noticeable loss of weight because of removal of sulfo-groups happens at temperatures above than 330° C. In the example under consideration, the pyrolysis temperature was 350° C. The heating of the anisotropic crystal layer was carried out using a thermal source located in a part of the substrate. The external thermal action on the anisotropic crystal layer was performed for about 10 minutes in the atmosphere of nitrogen. The decrease of solubility in polar solvents confirms that fact, that from a sample the part of sulfo-groups was removed.

The area of the local external influence represented a circle with a diameter of 1 cm. Another exemplary variant of the external action is the treatment of the anisotropic crystal layer with a microwave and/or laser radiation at a frequency in resonance with at least one absorption band of the organic substance. As a result of the external action, the treated part of the anisotropic crystal layer becomes insoluble in polar solvents.

Then, the anisotropic layer was covered with a mask having openings above the areas with removed ionic groups, after which the unmasked material was dissolved in a polar solvent. Through the openings in the mask, a metal (aluminum) electrode was deposited to obtain the top (cathode) contact of the device. The thickness of this layer was about 50-100 Å. In this example, the thickness of this metal layer was selected so that the metal coating would serve as a reflective layer with the reflection coefficient of not less than 95%. Then, the manufactured multilayer structure was washed in a polar solvent, for example, in water, in order to remove the mask layer (the layer of metal deposited onto the mask layer is removed as well). Finally, the anisotropic crystal layer was dissolved in the areas not subjected to the external action (from which ionogenic groups were not removed). As the result of the above-described technological operations, an organic photosensitive optoelectronic device was formed with the top contact (cathode) made of metal and the bottom contact (anode) made of ITO.

### EXAMPLE 2

A two-layer organic photosensitive optoelectronic device.

An indium tin oxide (ITO) coated glass provided the transparent conducting substrate on which a layer of copper phthalocyanine about 300 Å thick was formed by the conventional vacuum deposition technique. Copper phthalocyanine is thermally very stable, thus allowing the deposition by vacuum evaporation requiring a source temperature of about 500° C. During deposition, the substrate is maintained nominally at room temperature. The next organic photoelectric layer with a thickness of about 500 Å was deposited above the copper phthalocyanine layer. This layer was obtained by a method described in the first example from a lyotropic liquid crystal based on an organic dye (indanthrone sulfonate). Finally, an opaque Ag layer was deposited above said organic photoelectric layer. The area of the Ag electrode (˜0.1 cm²) determined the active area of the organic photosensitive optoelectronic device.

### EXAMPLE 3

An organic photosensitive optoelectronic device comprising a system of subcells connected in series.

Exemplary embodiments were fabricated on pre-cleaned ITO glass substrates, spin-coated with a 300 Å thick layer of poly (ethylenedioxythiophene) (PEDOT) (polystyrene sulfonate). Spin coating was performed for 40 sec at 4000 rpm and followed by drying at 110° C. for 1 hour at a reduced pressure. The organic photosensitive optoelectronic device layers were formed on the ITO/PEDOT glass substrate in the following sequence: DAMDAM (where D, A, and M denote electron donor, electron acceptor, and metal layers, respectively). The thickness of individual layers was controlled by use of, for example, a quartz piezocrystal thickness monitor. Copper phthalocyanine (CuPc) was used as a donor material. An electron acceptor layer was formed as described in the first example. This layer was formed from a lyotropic liquid crystal based on an organic dye (indanthrone sulfonate). Thin (5-20 Å) metal layer (Ag) were used as interlayers between the front and back subcells. The top (800 Å thick) metal electrode (Ag) was deposited through shadow mask of circular shape with a 1 mm diameter hole.

The foregoing descriptions of specific embodiments of the invention have presented for the purpose of illustration and description. They are not intended to be exhaustive or to limit the invention to the precise forms disclosed, and obviously many modifications, embodiments, and variations are possible in light of the above teaching. It is intended that the scope of the invention be defined by the claims appended hereto and their equivalents.

What is claimed is:

1. An organic optoelectronic device comprising
a multi-layer structure comprised of
a first electrode layer,
a second electrode layer, and
at least one organic photoelectric layer,
wherein said organic photoelectric layer is an anisotropically absorbing and electrically conducting layer, is comprised of rodlike supramolecules which comprise at least one polycyclic organic compound with a conjugated π-system, has a globally ordered crystal structure with an intermolecular spacing of 3.4±0.3 Å along a polarization axis of said organic photoelectric layer, and absorbs electromagnetic radiation in a predetermined spectral subrange of approximately 200 to 3000 nm, and
a substrate,
wherein said multi-layer structure is formed on one side of said substrate, and at least one of said first and second electrodes being transparent for the electromagnetic radiation to which the optoelectronic device is sensitive.

2. The device according to claim 1, comprising one said organic photoelectric layer located between the first and second electrodes, wherein said first electrode is a front transparent electrode and is located between a source of the electromagnetic radiation and said organic photoelectric layer, and said second electrode is a rear electrode.

3. The device according to claim 2, wherein the rear electrode is a reflective electrode for the electromagnetic radiation incident upon the device, and the device further comprises an additional retarder layer which is located between said reflective electrode and said photoelectric layer, wherein the thickness and optical anisotropy of said retarder layer are selected so as to ensure a 45° rotation of the polarization vector of said electromagnetic radiation.

4. The device according to claim 3, wherein the reflective electrode has a reflection coefficient of not less than 95% for the electromagnetic radiation incident upon the device.

5. The device according to claim 2, wherein the front electrode serves as a cathode and the rear electrode serves as an anode.

6. The device according to claim 2, wherein the front electrode serves as an anode and the rear electrode serves as a cathode.

7. The device according to claim 5 or 6, further comprising at least one electron transport layer situated between said organic photoelectric layer and said cathode.

8. The device according to claim 7, further comprising at least one exciton blocking layer situated between said organic photoelectric layer and the electron transport layer.

9. The device according to claim 5 or 6, further comprising at least one hole transport layer situated between said organic photoelectric layer and said anode.

10. The device according to claim 9, further comprising at least one exciton blocking layer situated between said organic photoelectric layer and the hole transport layer.

11. The device according to claim 1, comprising one said organic photoelectric layer, wherein the first electrode formed on one part of a surface of the organic photoelectric layer facing a source of the electromagnetic radiation incident on the device and the second electrode formed on another part of said front surface of said organic photoelectric layer, wherein the first electrode serves as a cathode and the second electrode serves as an anode.

12. The device according to claim 11, further comprising a retarder layer which is formed on the surface of said organic photoelectric layer which is opposite to a source of the electromagnetic radiation, and a reflective layer which is formed on said retarder layer, and wherein the thickness and optical anisotropy of said retarder layer are selected so as to ensure a 45° rotation of the polarization vector of the electromagnetic radiation incident upon the device.

13. The device according to claim 12, wherein the reflective layer has a reflection coefficient of not less than 95% for the electromagnetic radiation incident upon the device.

14. The device according to claim 1, comprising first and second said organic photoelectric layers, wherein said first organic photoelectric layer is an electron donor layer, and said second organic photoelectric layer is an electron acceptor layer and contacts with the first organic photoelectric layer forming a photovoltaic heterojunction, wherein said first and second organic photoelectric layers are located between the first and second electrodes, wherein the first electrode is located between a source of the electromagnetic radiation and said organic photoelectric layers and is a front transparent electrode, and the second electrode is a rear electrode.

15. The device according to claim 14, wherein the rear electrode is a reflective electrode for the electromagnetic radiation incident upon the device, and the device further comprises a retarder layer located between said reflective electrode and said first and second organic photoelectric layers, wherein the thickness and optical anisotropy of said retarder layer are selected so as to ensure a 45° rotation of the polarization vector of said electromagnetic radiation.

16. The device according to claim 15, wherein the reflective electrode has a reflection coefficient of not less than 95% for the electromagnetic radiation incident upon the device.

17. The device according to claim 14, wherein the front electrode serves as a cathode and the rear electrode serves as an anode.

18. The device according to claim 14, wherein the front electrode serves as an anode and the rear electrode serves as a cathode.

19. The device according to claim 17 or 18, further comprising at least one electron transport layer situated between said organic photoelectric layers and said cathode.

20. The device according to claim 19, further comprising at least one exciton blocking layer situated between said organic photoelectric layers and the electron transport layer.

21. The device according to claim 17 or 18, further comprising at least one hole transport layer situated between said organic photoelectric layers and said anode.

22. The device according to claim 21, further comprising at least one exciton blocking layer situated between said organic photoelectric layer and the hole transport layer.

23. The device according to claim 1, comprising at least two said organic photoelectric layers, wherein the polarization axes of the sequential organic photoelectric layers are parallel.

24. The device according to claim 1, comprising at least two said organic photoelectric layers, wherein the polarization axes of the sequential organic photoelectric layers are mutually perpendicular.

25. The device according to claim 1, further comprising a protective transparent layer formed on external surface of said device.

26. The device according to claim 1, further comprising an additional antireflection coating formed on an external surface of said device.

27. A multielement organic photosensitive optoelectronic device comprising
a system of organic photovoltaic elements, wherein each said element comprising
a transparent cathode,
at least one organic photoelectric layer, and
a transparent anode,
wherein said organic photoelectric layer is an anisotropically absorbing and electrically conducting layer, is comprised of rodlike supramolecules, which comprise at least one polycyclic organic compound with a conjugated π-system, has a globally ordered crystal structure with an intermolecular spacing of 3.4±0.3 Å along a polarization axis of said organic photoelectric layer, and absorbs an electromagnetic radiation in a predetermined spectral subrange from about 200 to 3000 nm, and wherein said organic photovoltaic elements being superimposed onto each other and electrically connected in parallel, and
a substrate,
wherein said system of organic photovoltaic elements is formed on one side of said substrate.

28. The device according to claim 27, wherein said organic photovoltaic elements have capability to absorb an electromagnetic radiation in a predetermined spectral subrange of about 200 to 3000 nm.

29. The device according to claim 27, further comprising a transparent isolating layer positioned between said organic photovoltaic elements.

30. The device according to claim 27, wherein said substrate is transparent for the electromagnetic radiation and the device further comprising a retarder layer and a reflective layer, wherein the retarder layer is located on the organic photovoltaic element most distant from said substrate, and the reflective layer is located on said retarder layer, and wherein the thickness and optical anisotropy of said retarder layer are selected so as to provide for a 45° rotation of the polarization vector of said electromagnetic radiation.

31. The device according to claim 27, further comprising a reflective layer and a retarder layer, wherein the reflective layer is situated on the substrate and the retarder is situated between said reflective layer and the organic photovoltaic element closest to said substrate, and wherein the thickness and optical anisotropy of said retarder are selected so as to provide for a 45° rotation of the polarization vector of the electromagnetic radiation incident upon the device.

32. The device according to claim 30 or 31, wherein the reflective layer has a reflection coefficient of not less than 95% for the electromagnetic radiation incident upon the device.

33. The device according to claim 27, wherein said substrate represents a reflector having a reflection coefficient not less than 95% for the electromagnetic radiation, and the device further comprises a retarder layer situated between said substrate and the photoelectric element closest to the substrate, the thickness and optical anisotropy of said retarder layer are selected so as to provide for a 45° rotation of the polarization vector of said electromagnetic radiation.

34. An organic photosensitive optoelectronic device comprising
a first electrode that serves as a cathode,
a second electrode that serves as an anode, and
a system of organic photovoltaic subcells connected in series and separated by electron-hole recombination zones,
wherein each said subcell comprises an organic photoelectric layer acting as an electron donor in contact with another organic photoelectric layer acting as an electron acceptor, and wherein at least one said photoelectric layer in at least one subcell is an anisotropically absorbing and electrically conducting layer, is comprised of rodlike supramolecules which comprise at least one polycyclic organic compound with a conjugated π-system, has a globally ordered crystal structure with an intermolecular spacing of 3.4±0.3 Å along a polarization axis of said layer, and absorbs electromagnetic radiation in a predetermined spectral subrange of about 200 to 3000 nm, and
a substrate supporting said first and second electrodes and at least one said subcell,
wherein at least one of said first and second electrodes being transparent for the incident electromagnetic radiation to which the optoelectronic device is sensitive.

35. The device according to claim 34, wherein the values of currents, generated by each said subcell, are approximately equal.

36. The device according to claim 34, further comprising an exciton blocking layer situated between the electron acceptor layer and the cathode.

37. The device according to claim 34, wherein said electron-hole recombination zone is a semitransparent metal layer.

38. The device according to claim 34, wherein said electron-hole recombination zone is a region of electrically active defects.

39. The device according to claim 34, wherein said subcells are selected so as to possess an ability to absorb an electromagnetic radiation in predetermined spectral subranges.

40. The device according to claim 34, wherein one of the first and second electrodes represents a reflective layer with a reflection coefficient of not less than 95% for the electromagnetic radiation incident upon the device, and said device further comprises a retarder layer introduced between said reflective layer and said system of subcells, wherein the thickness and optical anisotropy of the retarder layer are selected so as to ensure a 45° rotation of the polarization vector of said electromagnetic radiation.

41. A method for obtaining an anisotropically absorbing and electrically conducting layer comprising the steps of:
providing a substrate,
deposition by means of Cascade Crystallization Process of at least one conjugated aromatic crystalline layer onto said substrate,
wherein said conjugated aromatic crystalline layer is characterized by a globally ordered crystalline structure with an intermolecular spacing of 3.4±0.3 Å along a polarization axis of said layer, and formed by rodlike supramolecules, which comprise at least one polycyclic organic compound with a conjugated π-system and ionogenic groups, and
application of an external action upon at least one deposited conjugated aromatic crystalline layer,
wherein said external action is characterized by duration, character and intensity which are selected so as to ensure a partial removal of part of ionogenic groups from the conjugated aromatic crystalline layer while retaining the crystalline structure intact after termination of the external action.

42. The method according to claim 41, wherein the external action on the conjugated aromatic crystalline layer is applied by local or total heating of the conjugated aromatic crystalline layer up to a pyrolysis temperature.

43. The method according to claim 41, wherein the ionogenic group is one or several ionogenic groups selected from the list consisting of sulfonic, sulfate, and sulfite groups.

44. The method according to claim 43, wherein the external action on the conjugated aromatic crystalline layer is applied by local or total heating of the conjugated aromatic crystalline layer up to a temperature, which value is in the range between 330° C. and 350° C.

45. The method according to claim 41, wherein the ionogenic groups are selected from the list comprising COO—, P4—, cation groups, carboxy groups, and other ionogenic (hydrophilic) groups.

46. The method according to claim 41, wherein the partial removal step removes between 45 and 95% of the ionogenic groups, which are present in the conjugated aromatic crystalline layer before the external action.

47. The method according to claim 41, wherein the external action is performed by at least a partial treatment of the conjugated aromatic crystalline layer with microwave and/or laser radiation the frequency of which is selected so as to be in resonance with at least one absorption wavelength band of the organic compound.

48. The method according to claim 41, wherein the organic compound comprises at least one aromatic compound with the general structural formula {R} {F}n, where R is a polycyclic organic compound with conjugated π-systems, the structure of which contains one or more ionogenic groups, either like or unlike, ensuring the solubility in polar solvents for formation of a lyotropic liquid crystal phase; F are modifying functional groups; and n is the number of functional groups.
